(19) United States
(12) Patent Application Publication
(10) Pub. No.: US 2024/0332889 A1
(43) Pub. Date: Oct. 3, 2024

(54) LASER DEVICE AND LASER SOURCE ASSEMBLY

(71) Applicant: HISENSE LASER DISPLAY CO., LTD, Qingdao (CN)

(72) Inventors: Ke YAN, Qingdao (CN); Youliang TIAN, Qingdao (CN); Wei LI, Qingdao (CN); Zinan ZHOU, Qingdao (CN); Yao LU, Qingdao (CN); Xin ZHANG, Qingdao (CN)

(73) Assignee: HISENSE LASER DISPLAY CO., LTD, Qingdao (CN)

(21) Appl. No.: 18/740,768

(22) Filed: Jun. 12, 2024

Related U.S. Application Data
(63) Continuation of application No. PCT/CN2022/138479, filed on Dec. 12, 2022.

(30) Foreign Application Priority Data
Dec. 13, 2021 (CN) 202111515693.4
Dec. 13, 2021 (CN) 202123123529.7
Mar. 14, 2022 (CN) 202210246346.4
Mar. 14, 2022 (CN) 202220551575.2

(51) Int. Cl. H01S 5/02253; G03B 21/20; H01S 5/02255; H01S 5/0239; H01S 5/024; H01S 5/40

(52) U.S. Cl. CPC H01S 5/02253; H01S 5/02255; H01S 5/0239; H01S 5/02469; H01S 5/4031; H01S 5/4093; G03B 21/2033

(57) ABSTRACT

A laser device and a laser source assembly are provided. The laser device includes a base, a plurality of frames, a plurality of groups of laser chips, and a plurality of collimating lens groups. Any frame is correspondingly provided with a group of laser chips. Any group of laser chips includes a plurality of laser chips. Any collimating lens group includes a plurality of collimating lenses. The plurality of collimating lenses correspond to the plurality of laser chips, respectively. Any collimating lens is located on a laser-exit path of a corresponding laser chip.

### CROSS-REFERENCE TO RELATED APPLICATIONS

This application is a continuation application of International Patent Application No. PCT/CN2022/138479, filed on Dec. 12, 2022, which claims priority to Chinese Patent Application No. 202111515693.4, filed on Dec. 13, 2021; Chinese Patent Application No. 202123123529.7, filed on Dec. 13, 2021; Chinese Patent Application No. 202210246346.4, filed on Mar. 14, 2022; and Chinese Patent Application No. 202220551575.2, filed on Mar. 14, 2022, which are incorporated herein by reference in their entireties.

### TECHNICAL FIELD

The present disclosure relates to the field of photoelectric technologies and, in particular, to a laser device and a laser source assembly.

### BACKGROUND

With the development of photoelectric technologies, a laser device has been used widely. For example, the laser device may be used as a laser source for a laser projection apparatus or a laser television.

### SUMMARY

In an aspect, a laser device is provided. The laser device includes a base, a plurality of frames, a plurality of groups of laser chips, and a plurality of collimating lens groups. The plurality of frames are disposed on the base. The plurality of groups of laser chips are disposed on the base. Any of the plurality of frames is correspondingly provided with a group of laser chips. Any of the plurality of groups of laser chips includes a plurality of laser chips. The plurality of groups of laser chips satisfy at least one of following: different groups of laser chips in the plurality of groups of laser chips are configured to emit laser beams of different colors; or the plurality of laser chips of at least one of the plurality of groups of laser chips are configured to emit the laser beams of different colors. The plurality of collimating lens groups correspond to the plurality of groups of laser chips, respectively. Any of the plurality of collimating lens groups is located on a side of a corresponding group of laser chips away from the base. The any collimating lens group includes a plurality of collimating lenses, and the plurality of collimating lenses correspond to the plurality of laser chips, respectively. Any of the plurality of collimating lenses is located on a laser-exit path of a corresponding laser chip. The plurality of laser chips in the any group of laser chips are arranged in a row, and an arrangement direction of the plurality of laser chips is parallel to a slow axis direction of the laser beams emitted by the laser chips. The laser device satisfies at least one of following: an arrangement direction of the plurality of frames is parallel to a fast axis direction of the laser beams exiting from the any frame; or an arrangement direction of the plurality of collimating lens groups is parallel to the fast axis direction of the laser beams exiting from the any frame, and an arrangement direction of the plurality of collimating lenses of the any collimating lens group is parallel to the slow axis direction of the laser beams exiting from the corresponding laser chips.

In another aspect, a laser source assembly is provided. The laser source assembly includes a laser device, a combining lens group, a light homogenizing component, and a diffusion component. The laser device is configured to emit laser beams and includes a base, a plurality of frames, a plurality of groups of laser chips, and a plurality of collimating lens groups. The plurality of frames are disposed on the base. The plurality of groups of laser chips are disposed on the base. Any of the plurality of frames is correspondingly provided with a group of laser chips. Any of the plurality of groups of laser chips includes a plurality of laser chips. The plurality of groups of laser chips satisfy at least one of following: different groups of laser chips in the plurality of groups of laser chips are configured to emit the laser beams of different colors; or the plurality of laser chips of at least one of the plurality of groups of laser chips are configured to emit the laser beams of different colors. The plurality of collimating lens groups correspond to the plurality of groups of laser chips, respectively. Any of the plurality of collimating lens groups is located on a side of a corresponding group of laser chips away from the base. The any collimating lens group includes a plurality of collimating lenses, and the plurality of collimating lenses correspond to the plurality of laser chips, respectively. Any of the plurality of collimating lenses is located on a laser-exit path of a corresponding laser chip. The plurality of laser chips in the any group of laser chips are arranged in a row, and an arrangement direction of the plurality of laser chips is parallel to a slow axis direction of the laser beams emitted by the laser chips, and the laser device satisfies at least one of following: an arrangement direction of the plurality of frames is parallel to a fast axis direction of the laser beams exiting from the any frame; or an arrangement direction of the plurality of collimating lens groups is parallel to the fast axis direction of the laser beams exiting from the any frame, and an arrangement direction of the plurality of collimating lenses of the any collimating lens group is parallel to the slow axis direction of the laser beams exiting from the corresponding laser chips. The combining lens group is located on a laser-exit side of the laser device and configured to combine the laser beams emitted by the laser device. The light homogenizing component is located on a laser-exit side of the combining lens group and configured to increase a divergence angle of the combined laser beam in at least one of a fast axis direction or a slow axis direction, so as to homogenize the combined laser beam. The diffusion component is located between the combining lens group and the light homogenizing component and configured to receive the combined laser beam and diffuse the combined laser beam. The diffusion component is capable of vibrating or rotating.

### BRIEF DESCRIPTION OF THE DRAWINGS

FIG. 1 is a top view of a laser device in the related art;

FIG. 2 is an exploded view of a laser device, in accordance with some embodiments;

FIG. 3 is a top view of a laser device, in accordance with some embodiments;

FIG. 4 is a sectional view of the laser device in FIG. 3 taken along the line A-A;

FIG. 5 is a top view of another laser device, in accordance with some embodiments;

FIG. 6 is a top view of yet another laser device, in accordance with some embodiments;

FIG. 7 is a top view of yet another laser device, in accordance with some embodiments;

FIG. 8 is a sectional view of the laser device in FIG. 7 taken along the line B-B;

FIG. 9 is a diagram showing a structure of yet another laser device, in accordance with some embodiments;

FIG. 10 is a sectional view of the laser device in FIG. 9 taken along the line C-C;

FIG. 11 is a top view of the laser device in FIG. 9;

FIG. 12 is a top view of yet another laser device, in accordance with some embodiments;

FIG. 13 is a diagram showing a structure of a laser source assembly, in accordance with some embodiments;

FIG. 14A is a diagram showing a principle of a beam path of a laser source assembly, in accordance with some embodiments;

FIG. 14B is a diagram showing a principle of a beam path of another laser source assembly, in accordance with some embodiments; and

FIG. 15 is a diagram showing a principle of a beam path of yet another laser source assembly, in accordance with some embodiments.

### DETAILED DESCRIPTION

Some embodiments of the present disclosure will be clearly and completely described below with reference to the accompanying drawings. However, the described embodiments are merely some, but not all embodiments of the present disclosure. All other embodiments obtained by a person of ordinary skill in the art based on embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as an open and inclusive meaning, i.e., “including, but not limited to.” In the description, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the terms such as “first” and “second” are used for descriptive purposes only and are not to be construed as indicating or implying the relative importance or implicitly indicating the number of indicated technical features. Thus, features defined by “first” or “second” may explicitly or implicitly include one or more of the features. In the description of the embodiments of the present disclosure, the term “a plurality of” or “the plurality of” means two or more unless otherwise specified.

In the description of some embodiments, the term “connected” and derivatives thereof may be used. The term “connected” should be understood in a broad sense. For example, the term “connected” may represent a fixed connection, a detachable connection, or a one-piece connection, or may represent a direct connection, or may represent an indirect connection through an intermediate medium. The embodiments disclosed herein are not necessarily limited to the content herein.

The phrase “at least one of A, B, and C” has the same meaning as the phrase “at least one of A, B, or C,” both including the following combinations of A, B, and C: only A, only B, only C, a combination of A and B, a combination of A and C, a combination of B and C, and a combination of A, B, and C.

The use of the phase “applicable to” or “configured to” herein means an open and inclusive expression, which does not exclude devices that are applicable to or configured to perform additional tasks or steps.

In addition, the use of the phrase “based on” is meant to be open and inclusive, since a process, step, calculation, or other action that is “based on” one or more of the stated conditions or values may, in practice, be based on additional conditions or value exceeding those stated.

The terms such as “about,” “substantially,” and “approximately” as used herein include a stated value and an average value within an acceptable range of deviation of a particular value. The acceptable range of deviation is determined by a person of ordinary skill in the art, considering measurement in question and errors associated with measurement of a particular quantity (i.e., limitations of a measurement system).

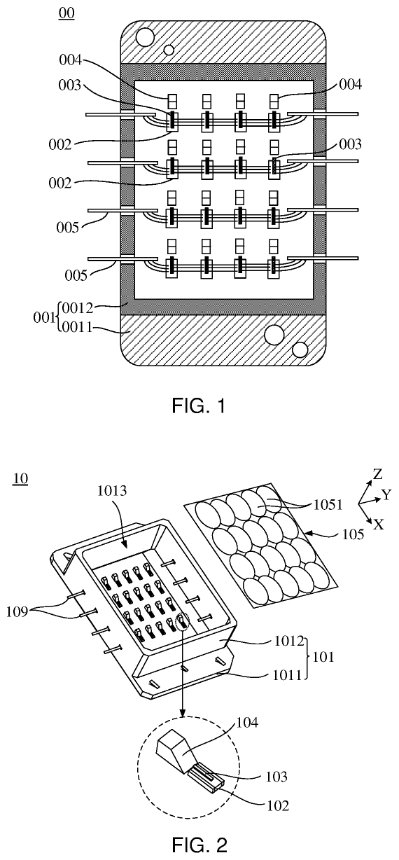

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable deviation range of the approximate parallelism may be, for example, a deviation within 5°. The term “perpendicular” includes absolute perpendicularity and approximate perpendicularity, and an acceptable deviation range of the approximate perpendicularity may also be, for example, a deviation within 5°. The term “equal” includes absolute equality and approximate equality, and an acceptable deviation range of the approximate equality may be that, for example, a difference between the two that are equal is less than or equal to 5% of either of the two. FIG. 1 is a top view of a laser device in the related art.

As shown in FIG. 1, generally, a multi-color laser device 00 includes a tube shell 001, a plurality of heat sinks 002, a plurality of laser chips 003, a plurality of prisms 004, and a plurality of conductive pins 005. The tube shell 001 includes a substrate 0011 and a frame 0012 disposed on the substrate 0011. The plurality of laser chips 003 are arranged in a plurality of rows (e.g., four rows), and the laser chips 003 in a same row are configured to emit laser beams of a same color. The plurality of conductive pins 005 are disposed on the frame 0012 and are evenly distributed on two opposite sides of the frame 0012. The number of the conductive pins 005 on either side of the opposite sides of the frame 0012 is the same as the number of rows of the plurality of laser chips 003. The plurality of conductive pins 005 include a plurality of positive pins and a plurality of negative pins. The plurality of positive pins are located on a first side of the frame 0012, and the plurality of negative pins are located on a second side of the frame 0012. The first side of the frame 0012 and the second side of the frame 0012 are opposite to each other.

For example, the first row of laser chips 003 are configured to emit green laser beams, the second row of laser chips 003 are configured to emit blue laser beams, and the third row of laser chips 003 and the fourth row of laser chips 003 are configured to emit red laser beams. In this case, any type of laser chips 003 are arranged in at least one row, and any row of laser chips 003 is connected to a positive pin and a negative pin. The positive pins connected to different rows of laser chips 003 are different and the negative pins connected to different rows of laser chips 003 are different, so that the multi-color laser device 00 has a large volume, which is not conducive to the miniaturization of the multi-color laser device 00.

In some embodiments of the present disclosure, a laser device 10 is provided. FIG. 2 is an exploded view of a laser device, in accordance with some embodiments. As shown in FIG. 2, the laser device 10 includes a tube shell 101, at least one heat sink 102, a plurality of groups of laser chips 103, at least one prism 104, and a collimating lens group 105.

The tube shell 101 is configured to encapsulate the plurality of groups of laser chips 103. The tube shell 101 includes a substrate 1011 and a frame 1012 disposed on the substrate 1011, and the frame 1012 has a hollow inner cavity 1013. The at least one heat sink 102, the plurality of groups of laser chips 103, and the at least one prism 104 are located in the inner cavity 1013 of the frame 1012. The collimating lens group 105 is covered on the frame 1012, so as to close an inner cavity (i.e., the inner cavity 1013 of the frame 1012) of the tube shell 101.

It will be noted that the present disclosure does not limit a material of the tube shell 101. In some embodiments, the tube shell 101 may be made of copper, such as oxygen-free copper. Since copper has a high thermal conductivity, by selecting copper as the material of the tube shell 101, the heat generated by the plurality of groups of laser chips 103 disposed on the substrate 1011 during operation may be quickly conducted and dissipated through the tube shell 101, so as to avoid damage to the plurality of groups of laser chips 103 due to heat accumulation. In some embodiments, the material of the tube shell 101 may include one or more of aluminum, copper, aluminum nitride, or silicon carbide.

The substrate 1011 and the frame 1012 may be separate piece members or may also be a one-piece member. In some embodiments, in a case where the substrate 1011 and the frame 1012 are separate piece members, the substrate 1011 and the frame 1012 may be soldered together by using a parallel gap seam welding technique. In some other embodiments, in a case where the substrate 1011 and the frame 1012 are a one-piece member, the substrate 1011 has high flatness and the plurality of groups of laser chips 103 disposed on the substrate 1011 have a high reliability, so that the laser beams emitted by the plurality of groups of laser chips 103 may exit at a preset light-emitting angle, thereby improving the light-emitting effect of the laser device 10.

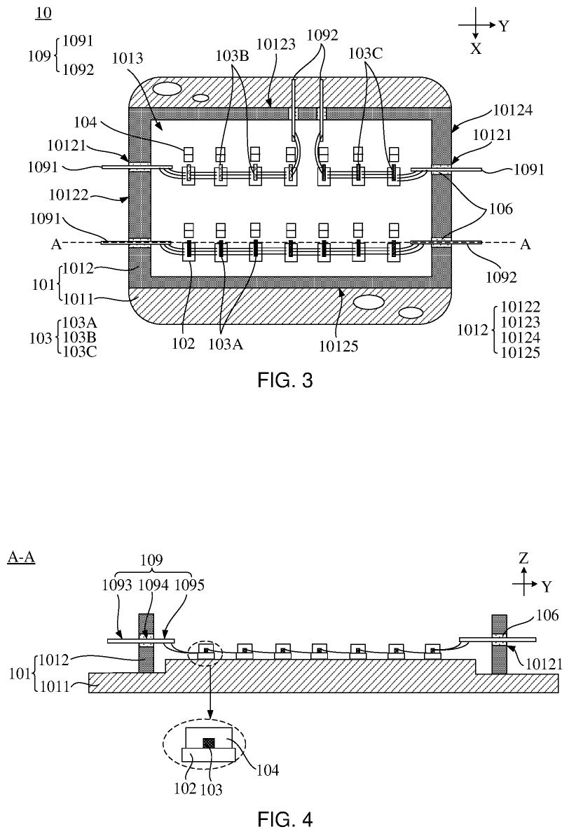

FIG. 3 is a top view of a laser device, in accordance with some embodiments. FIG. 4 is a sectional view of the laser device in FIG. 3 taken along the line A-A.

In some embodiments, the frame 1012 has a structure of a square ring, and an orthogonal projection of the frame 1012 on the substrate 1011 is in a shape of a square ring or a quasi-square ring. The shape of a quasi-square ring includes a shape of a square ring with rounded corners (i.e., a shape obtained by replacing square corners of a shape of a square ring with rounded corners) and a shape of a square ring with chamfered corners (i.e., a shape obtained by replacing square corners of a shape of a square ring with chamfered corners). For example, as shown in FIGS. 2 and 3, the orthogonal projection of the frame 1012 on the substrate 1011 is in a shape of a rectangular ring. Here, a first direction Y may be a length direction of the shape of the rectangular ring, a second direction X may be a width direction of the shape of the rectangular ring, and a third direction Z may be a height direction of the frame 1012. However, the present disclosure is not limited thereto.

As shown in FIG. 3, the frame 1012 includes four side walls. The four side walls are a first side wall 10122 and a third side wall 10124 disposed opposite to each other in the first direction Y, and a second side wall 10123 and a fourth side wall 10125 disposed opposite to each other in the second direction X. The first side wall 10122, the second side wall 10123, the third side wall 10124, the fourth side wall 10125, and the first side wall 10122 are sequentially connected, so as to form the frame 1012.

Different groups of laser chips 103 in the plurality of groups of laser chips 103 are configured to emit laser beams of different colors. Any group of laser chips 103 includes a plurality of laser chips 103, and any laser chip 103 is configured to emit a laser beam of one color.

In some embodiments, as shown in FIGS. 3 and 4, the plurality of groups (e.g., two groups) of laser chips 103 are located in the inner cavity 1013 of the frame 1012.

In some embodiments, the plurality of laser chips 103 emitting laser beams of a same color in any group of laser chips 103 may be arranged adjacent to each other, which is conducive to contracting a beam spot of the laser beams of a same color.

In some embodiments, at least one group of laser chips 103 in the plurality of groups of laser chips 103 may include a plurality of laser chips 103 emitting laser beams of different colors.

In some embodiments, at least one laser chip 103 in the at least one group of laser chips 103 may be arranged adjacent to at least one laser chips 103 emitting a laser beam of a different color, which is conducive to improving the overlap of beam spots of laser beams of different colors.

The laser chip 103 may include a first electrode, a second electrode, and a light-emitting structure located between the first electrode and the second electrode. The first electrode is electrically connected to a positive electrode of an external power supply, and the second electrode is electrically connected to a negative electrode of the external power supply. The first electrode and the second electrode are configured to receive a current required for a laser beam of a color and transmit the current to the light-emitting structure, so that the current excites the light-emitting structure to emit the laser beam of the color. The first electrode and the second electrode are electrodes with opposite polarities. For example, the first electrode is a positive electrode and the second electrode is a negative electrode; alternatively, the first electrode is a negative electrode and the second electrode is a positive electrode.

The plurality of groups of laser chips 103 may have a same laser-exit direction. As shown in FIG. 2, the first direction Y is a direction perpendicular to the laser-exit direction of the laser chips 103, and the second direction X is a direction parallel to the laser-exit direction of the laser chips 103. Here, the laser-exit direction of the laser chips 103 may be opposite to the second direction X. The plurality of laser chips 103 in any group of laser chips 103 are arranged in sequence in the first direction Y, and the plurality of groups of laser chips 103 are arranged in sequence in the second direction X.

It will be noted that the present disclosure does not limit the number of groups of laser chips 103, and the laser device 10 may include two, three, four, or more groups of laser chips 103. Moreover, the present disclosure does not limit the number of the plurality of laser chips 103 in any group of laser chips 103, and any group of laser chips 103 may include two, three, four, five, six, or more laser chips 103.

One (e.g., each) heat sink 102 corresponds to one or more laser chips 103, and one (e.g., each) prism 104 corresponds to one or more laser chips 103.

The heat sink 102 is configured to assist heat dissipation of a corresponding laser chip 103. The heat sink 102 is disposed on the substrate 1011, and the laser chip 103 is disposed on a side of a corresponding heat sink 102 away from the substrate 1011. The heat sink 102 may be fixedly connected to the substrate 1011, and the laser chip 103 may be fixedly connected to the heat sink 102. However, the present disclosure is not limited thereto.

The prism 104 is located on a laser-exit side of one or more corresponding laser chips 103. The prism 104 may be a reflecting prism and configured to reflect the laser beam emitted by one or more corresponding laser chips 103. For example, the laser beam emitted by the laser chip 103 exits in a direction (e.g., the third direction Z shown in FIG. 2) away from the substrate 1011 through a corresponding reflecting prism. It will be noted that the first direction Y, the second direction X, and the third direction Z are perpendicular to each other.

There are two corresponding relations between the heat sink 102 and the prism 104 in quantity.

In the first corresponding relation, the plurality of prisms 104 correspond to the plurality of heat sinks 102, respectively. One or more laser chips 103 are disposed on any heat sink 102, and any prism 104 corresponds to the one or more laser chips 103 located on a corresponding heat sink 102. In this way, the size of the heat sink 102 and the size of the prism 104 may be reduced, which is conducive to the miniaturization of the laser device 10.

For example, a base area of the heat sink 102 may be a product of 1.3 mm and 1.7 mm (i.e., 1.3 mm×1.7 mm), and a base area of the prism 104 may be a product of 1 mm and 2 mm (i.e., 1 mm×2 mm). On this basis, the sizes of the heat sink 102 and the prism 104 may be further reduced, which is conducive to miniaturization of the laser device 10.

In the second corresponding relation, any prism 104 corresponds to two or more heat sinks 102, a laser chip 103 is disposed on any heat sink 102, and any prism 104 corresponds to two or more laser chips 103 located on the two or more corresponding heat sinks 102. In this way, the numbers of prisms 104 and heat sinks 102 may be reduced, which is conducive to the installation of the prisms 104 and the heat sinks 102 and improving production efficiency.

In some embodiments, the heat sink 102 includes a heat dissipation substrate and a conductive layer on the heat dissipation substrate. The laser chip 103 is located (e.g., fixed) on the conductive layer of a corresponding heat sink 102.

In some embodiments, a material of the heat dissipation substrate includes ceramic or a conductive material (e.g., copper), and a material of the conductive layer includes gold. It will be noted that the present disclosure does not limit the materials of the heat dissipation substrate and the conductive layer.

In some embodiments, in a case where the heat dissipation substrate is made of a conductive material, the heat sink 102 further includes an insulating layer disposed between the heat dissipation substrate and the conductive layer. The current from the external power supply may be ensured to be normally transmitted to the laser chip 103 by providing the insulating layer.

In some embodiments, the heat sink 102 further includes a solder layer disposed on the conductive layer, and the solder layer may fix the laser chip 103 on the conductive layer when being melted.

In some embodiments, the heat sink 102 has a conductive surface, and the conductive surface is a surface of the heat sink 102 away from the substrate 1011. The laser chip 103 is located on the conductive surface of the heat sink 102 and electrically connected to the electrode of the external power supply through the conductive surface. For example, the laser chip 103 is fixed on the heat sink 102, the first electrode of the laser chip 103 is connected to the conductive surface of the heat sink 102, and the conductive surface of the heat sink 102 is electrically connected to the electrode of the external power supply.

In this way, the first electrode of the laser chip 103 may be energized as long as a wire connected to the electrode of the external power supply is connected to the conductive surface, and there is no need to directly contact the wire with the first electrode of the laser chip 103.

In some embodiments, the laser chip 103 may be fixed on the heat sink 102, and the conductive surface of the heat sink 102 may be used as the first electrode of the laser chip 103 and electrically connected to the electrode of the external power supply. In this way, there is no need to provide a separate conductive film layer used as the first electrode in the laser chip 103.

The collimating lens group 105 is disposed on a side of the frame 1012 away from the substrate 1011. The collimating lens group 105 includes a plurality of collimating lenses 1051, and the plurality of collimating lenses 1051 correspond to the plurality of laser chips 103 in the plurality of groups of laser chips 103, respectively. One (e.g., each) collimating lens 1051 is located in a laser-exit path of a corresponding laser chip 103 and configured to adjust a divergent laser beam generated by the corresponding laser chip 103 to a parallel laser beam. That is to say, the collimating lens 1051 may collimate the laser beam.

The laser beam emitted by the laser chip 103 has a divergence angle. If the laser beam continues to propagate at the divergence angle, the beam spot formed by the laser beam will be enlarged, so that an energy density of the beam spot is reduced, which is not conducive to the subsequent use and operation of the laser beam. However, in some embodiments of the present disclosure, the collimating lens group 105 may collimate the laser beam emitted by the laser chip 103. The process of the collimating lens group 105 collimating the laser beam emitted by the laser chip 103 is a process of adjusting the divergence angle of the laser beam, so that the adjusted laser beam is approximately a parallel beam.

For example, the laser chip 103 emits a laser beam to a corresponding prism 104, and the laser beam is reflected to a corresponding collimating lens 1051 by the prism 104. After being collimated by the collimating lens 1051, the laser beam exits from the collimating lens 1051, so that the beam output of the laser device 10 is achieved. However, in some embodiments, the collimating lens group 105 may also be omitted.

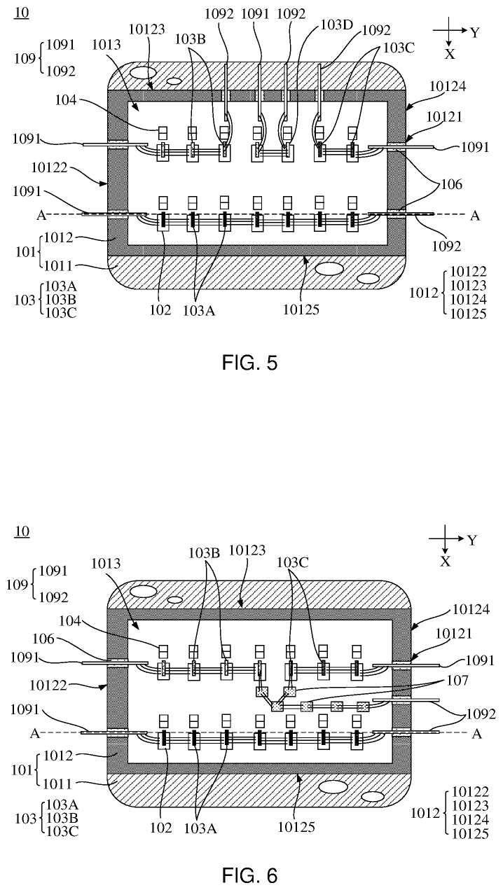

FIG. 5 is a top view of another laser device, in accordance with some embodiments. FIG. 6 is a top view of yet another laser device, in accordance with some embodiments. FIG. 4 may also be a sectional view of the laser device in FIG. 4 or 5 taken along the line A-A.

In some embodiments, as shown in FIGS. 2 and 3, the laser device 10 further includes a plurality of conductive pins 109 electrically connected to the external power supply. The plurality of conductive pins 109 are configured to transmit currents to the components (e.g., the plurality of groups of laser chips 103) connected thereof. The plurality of conductive pins 109 include a plurality of first electrode pins 1091 and at least one second electrode pin 1092. The first electrode pin 1091 and the second electrode pin 1092 are pins connected to opposite electrodes of the external power supply.

The first electrode pin 1091 is a positive pin, and the second electrode pin 1092 is a negative pin. Alternatively, the first electrode pin 1091 is a negative pin, and the second electrode pin 1092 is a positive pin. The first electrode pin (e.g., the positive pin) 1091 is connected to one electrode (e.g., the positive electrode) of the external power supply, the second electrode pin (e.g., the negative pin) 1092 is connected to another electrode (e.g., the negative electrode) of the external power supply, and any laser chip 103 is connected to one first electrode pin 1091 and one second electrode pin 1092. In this way, the external power supply may be electrically connected to the plurality of groups of laser chips 103 through the plurality of conductive pins 109, so as to achieve current transmission to the plurality of groups of laser chips 103.

For example, as shown in FIGS. 3, 5, and 6, the frame 1012 further includes a plurality of first openings 10121. The plurality of first openings 10121 are disposed on the side walls of the frame 1012, and plurality of first openings 10121 correspond to the plurality of conductive pins 109, respectively. The conductive pin 109 passes through a corresponding first opening 10121 and is fixedly connected to the side wall of the frame 1012. The conductive pin 109 includes three portions, which are a first portion 1093, a second portion 1094, and a third portion 1095 connected in sequence.

The first portion 1093 is a portion of the conductive pin 109 located outside the frame 1012, the second portion 1094 is a portion of the conductive pin 109 located in the first opening 10121, and the third portion 1095 is a portion of the conductive pin 109 passing through the first opening 10121 and extending into the inside of the frame 1012. The first portion 1093 of the conductive pin 109 is connected to an electrode (e.g., the positive electrode or the negative electrode) of the external power supply, and the third portion 1095 of the conductive pin 109 is connected to an electrode (e.g., the first electrode or the second electrode) of a corresponding laser chip 103 through a wire. In this way, the external power supply may transmit currents to the plurality of groups of laser chips 103 through the plurality of conductive pins 109.

In some embodiments, as shown in FIGS. 3, 5, and 6, the laser device 10 further includes a plurality of sealing insulators 106. The plurality of sealing insulators 106 correspond to the plurality of first openings 10121, respectively, so that the plurality of sealing insulators 106 may correspond to the plurality of conductive pins 109, respectively. The plurality of sealing insulators 106 are configured to fix the plurality of conductive pins 109 at positions of the first openings 10121 and seal the first openings 10121.

In some embodiments, the sealing insulator 106 is in a shape of a ring. During the assembly process, a sealing insulator 106 is first covered on a corresponding conductive pin 109, and then the covered conductive pin 109 is inserted into a corresponding first opening 10121, so that the sealing insulator 106 may be located in the corresponding first opening 10121 on the side wall of the frame 1012. Then, the sealing insulator 106 is heated. For example, the sealing insulator 106 is heated to 800° C. to 900° C. As a result, the sealing insulator 106 is melted to fill a gap between the conductive pin 109 and the side wall where the first opening 10121 is located. Next, the melted sealing insulator 106 is used as a sealing adhesive to bond the conductive pin 109 to the side wall where the first opening 10121 is located, so that fixing between the conductive pin 109 and the frame 1012 is achieved. Finally, the sealing insulator 106 is cooled and solidified after bonding.

In some embodiments, a material of the sealing insulator 106 includes glass, however, the present disclosure is not limited thereto.

Arrangement manners of the plurality of groups of laser chips 103 and connection manners between the plurality of groups of laser chips 103 and the plurality of conductive pins 109 in some embodiments of the present disclosure are described in detail below.

In some embodiments, slow axes of the laser beams emitted by any group of laser chips 103 may be parallel to the first direction Y.

There is a difference in the propagation speed of the laser beam in different light vector directions. A light vector direction where the laser beam propagates fast is a fast axis, and a light vector direction where the laser beam propagates slow is a slow axis. The fast axis of the laser beam is perpendicular to the slow axis of the laser beam.

In some embodiments, the fast axis of the laser beam may be perpendicular to a laser-exit surface of the laser chip 103, and the slow axis of the laser beam may be parallel to the laser-exit surface of the laser chip 103. A divergence angle of the laser beam in the fast axis is greater than that of the laser beam in the slow axis. For example, the divergence angle of the laser beam in the fast axis is equal to or greater than three times the divergence angle of the laser beam in the slow axis. Here, the laser-exit surface of the laser chip 103 may be understood as a plane parallel to the first direction Y and the second direction X.

In this way, the plurality of laser chips 103 in any group of laser chips 103 may be arranged with the slow axis of the emitted laser beam as an arrangement direction. Since the laser beam has a small divergence angle in the slow axis, it is possible to avoid that the laser beams emitted by adjacent laser chips 103 overlap and interfere with each other, and to reduce a distance between the plurality of laser chips 103 in any group of laser chips 103, so that an arrangement density of the laser chips 103 in the frame 1012 may be improved. In this way, the frame 1012 may have a small volume, and the volume of the laser device 10 may be reduced correspondingly, which is conducive to the miniaturization of the laser device 10.

In some embodiments, at least one group of laser chips 103 in the plurality of groups of laser chips 103 includes at least two types of laser chips 103, so that the number of groups of laser chips 103 may be less than the number of types of laser chips 103. The at least two types of laser chips 103 are located in at least two regions in the frame 1012, respectively, and the at least two regions are arranged in sequence along the first direction Y. Any type of laser chips 103 are configured to emit laser beams of one color, and different types of laser chips 103 emit laser beams of different colors.

As shown in FIGS. 3 and 6, the laser device 10 includes two groups of laser chips 103. The two groups of laser chips 103 are a first group of laser chips 103 and a second group of laser chips 103, respectively. The first group of laser chips 103 includes a first type of laser chips 103A, and the second group of laser chips 103 includes a second type of laser chips 103B and a third type of laser chips 103C.

The plurality of laser chips 103 in the first type of laser chips 103A are arranged in sequence in the first direction Y, and two regions where the second type of laser chips 103B and the third type of laser chips 103C are located are arranged in sequence in the first direction Y, so that any second type of laser chips 103B and any third type of laser chips 103C may be arranged in the first direction Y. A wavelength of the laser beams emitted by the first type of laser chips 103A is greater than that of the second type of laser chips 103B, and the wavelength of the second type of laser chips 103B is greater than that of the third type of laser chips 103C. The three types of laser chips 103 are configured to emit laser beams of different colors.

For example, the first type of laser chips 103A, the second type of laser chips 103B, and the third type of laser chips 103C are red laser chips, green laser chips, and blue laser chips, respectively. The three types of laser chips emit the red laser beams, the green laser beams, and the blue laser beams in sequence. It will be noted that the present disclosure does not limit the colors of the laser beams emitted by the laser chips 103. The laser chips 103 may also be laser chips emitting laser beams of yellow, purple, or other colors.

In some embodiments, the number of the first type of laser chips 103A is greater than the number of the second type of laser chips 103B and greater than the number of the third type of laser chips 103C.

In some embodiments, the number of the first type of laser chips 103A is less than or equal to a sum of the number of the second type of laser chips 103B and the number of the third type of laser chips 103C.

In some embodiments, the number of the first type of laser chips 103A is less than the sum of the number of the second type of laser chips 103B and the number of the third type of laser chips 103C, and the number of the second type of laser chips 103B is greater than the number of the third type of laser chips 103C.

In some embodiments, a difference between the wavelengths of laser beams emitted by the plurality of laser chips 103 in the first type of laser chips 103A is within a range of 4 nm to 10 nm, inclusive. For example, the difference between the wavelengths of laser beams emitted by the plurality of laser chips 103 in the first type of laser chips 103A is 4 nm, 5 nm, 6 nm, 7 nm, 8 nm, 9 nm, or 10 nm. It may be understood that the less the difference between the wavelengths of the plurality of laser beams, the more similar the colors of the plurality of laser beams, and thus the higher the color purity of the beam formed by the plurality of laser beams.

In some embodiments, the number of the second type of laser chips 103B is greater than or equal to the number of the third type of laser chips 103C.

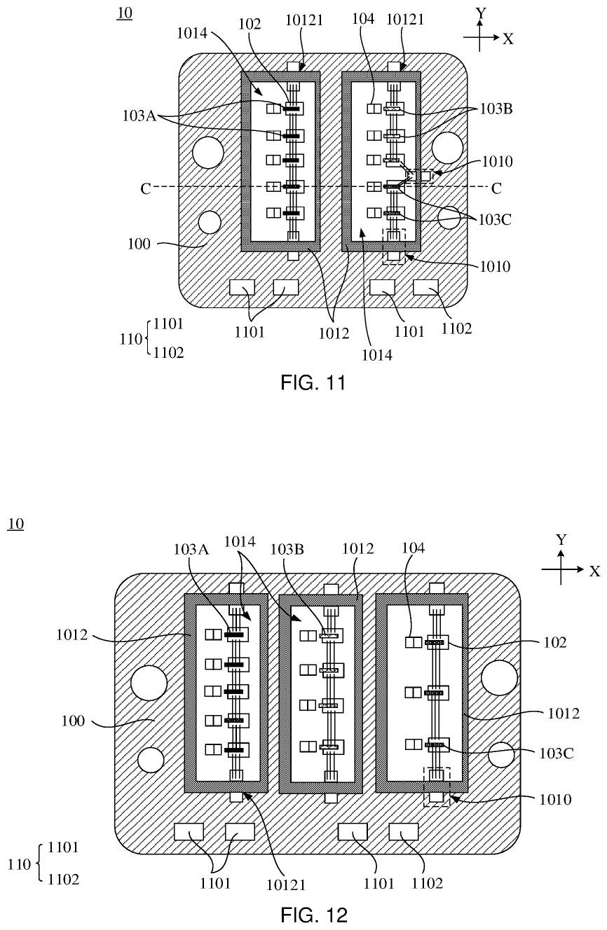

For example, as shown in FIGS. 3 and 6, the number of the first type of laser chips 103A is seven, the number of the second type of laser chips 103B is four, and the number of the third type of laser chips 103C is three. Alternatively, as shown in FIG. 11, the number of the first type of laser chips 103A is five, the number of the second type of laser chips 103B is three, and the number of the third type of laser chips 103C is two. In this case, the number of the first type of laser chips 103A is greater than the number of the second type of laser chips 103B, greater than the number of the third type of laser chips 103C, and equal to the sum of the number of the second type of laser chips 103B and the number of the third type of laser chips 103C. Moreover, the number of the second type of laser chips 103B is greater than the number of the third type of laser chips 103C.

For another example, the number of the first type of laser chips 103A is five, the number of the second type of laser chips 103B is four, and the number of the third type of laser chips 103C is three. Alternatively, the number of the first type of laser chips 103A is four, the number of the second type of laser chips 103B is three, and the number of the third type of laser chips 103C is two. In this case, the number of the first type of laser chips 103A is greater than the number of the second type of laser chips 103B, greater than the number of the third type of laser chips 103C, and less than the sum of the number of the second type of laser chips 103B and the number of the third type of laser chips 103C. Moreover, the number of the second type of laser chips 103B is greater than the number of the third type of laser chips 103C.

It will be noted that the present disclosure does not limit the number and quantity relation of the plurality of types of laser chips 103 in the plurality of groups of laser chips 103. The number and quantity relation of the plurality of types of laser chips 103 may be set and adjusted correspondingly according to a ratio of the laser beams of different colors that the laser device 10 is required to provide. In a case where a lot of blue laser beams are required, a lot of blue laser chips may be disposed in the laser device 10. Alternatively, in a case where a lot of green laser beams are required, a lot of green laser chips may be disposed in the laser device 10.

In the laser device 10 provided in some embodiments of the present disclosure, there is at least one group of laser chips 103 in the plurality of groups of laser chips 103, which includes at least two types of laser chips 103. The plurality of types of laser chips 103 in the plurality of groups of laser chips 103 correspond to a plurality of colors, respectively, and the plurality of types of laser chips 103 emit laser beams of different colors. In this way, a same type of laser chips 103 in the laser device 10 may be located in a same group (e.g., a row or a column), and there are at least two types of laser chips 103 located in a same group, so that the number of groups (e.g., the number of rows or the numbers of columns) of laser chips 103 is less than the number of types of laser chips 103. As a result, a lot of types of laser chips 103 may be disposed in the laser device 10 with a small volume, which is conducive to reducing the volume of the multi-color laser device and achieving the miniaturization of the multi-color laser device.

In some embodiments, at least one group of laser chips 103 in the plurality of groups of laser chips 103 may include at least three types of laser chips 103. The at least three types of laser chips 103 are located in at least three regions in the frame 1012, respectively, and the at least three regions are arranged in sequence in the first direction Y.

As shown in FIG. 5, the laser device 10 includes two groups of laser chips 103. The first group of laser chips 103 includes a first type of laser chips 103A, and the second group of laser chips 103 includes a second type of laser chips 103B, a third type of laser chips 103C, and a fourth type of laser chips 103D. The plurality of laser chips 103 in the first type of laser chips 103A are arranged in sequence in the first direction Y. Three regions where the second type of laser chips 103B, the fourth type of laser chips 103D, and the third type of laser chips 103C are located are arranged in sequence in the first direction Y. The fourth type of laser chips 103D is located between the second type of laser chips 103B and the third type of laser chips 103C.

In some embodiments, the number of the first type of laser chips 103A is greater than the number of the second type of laser chips 103B, the number of the third type of laser chips 103C, and the number of the fourth type of laser chips 103D.

In some embodiments, the number of the first type of laser chips 103A is less than or equal to a sum of the number of the second type of laser chips 103B, the number of the third type of laser chips 103C, and the number of the fourth type of laser chips 103D.

For example, as shown in FIG. 5, the number of the first type of laser chips 103A is seven, the number of the second type of laser chips 103B is three, the number of the third type of laser chips 103C is two, and the number of the fourth type of laser chips 103D is two. In this case, the number of the first type of laser chips 103A is greater than the number of the second type of laser chips 103B, the number of the third type of laser chips 103C, and the number of the fourth type of laser chips 103D, and equal to the sum of the number of second type of laser chips 103B, the number of third type of laser chips 103C, and the number of fourth type of laser chips 103D.

In some embodiments, as shown in FIGS. 3, 5 and 6, a same type of laser chips 103 in a same group of laser chips 103 are connected in series, and two ends of the type of laser chips 103 connected in series are connected to a first electrode pin 1091 and a second electrode pin 1092, respectively.

In some examples, wires are disposed between the plurality of laser chips 103 of a same type of laser chips 103 in a group of laser chips 103 by using a wire bonding process, so as to connect the plurality of laser chips 103 in series. For example, in a same type of laser chips 103 connected in series, the first electrode of one laser chip 103 is connected to the second electrode of an adjacent laser chip 103 by means of wires. The wire may be a gold wire, and a process of fixing the gold wire between the components in the laser device 10 may be referred to as a gold wire bonding process. A diameter of the gold wire may be within a range of 20 μm to 50 μm, inclusive. For example, the diameter of the gold wire is 20 μm, 25 μm, 30 μm, 35 μm, 40 μm, 45 μm, or 50 μm. The greater the diameter of the gold wire, the greater the fusing current of the gold wire. The fusing current is the maximum current that may pass the wire when the wire is fusing.

It will be noted that the two ends of any type of laser chips 103 in a same group of laser chips 103 refer to two connecting ends of the plurality of laser chips 103 connected in series. Since the plurality of laser chips 103 of any type of laser chips 103 in a same group of laser chips 103 are connected in series, one power switch may control the on and off of the plurality of laser chips 103. Moreover, since the currents at the positions in the series circuit of any type of laser chips 103 in a same group of laser chips 103 are equal to each other, the requirement for the input current is low, and the input current may easily equal to a threshold current of each laser chip 103, which is helpful for the laser chip 103 to emit the laser beam.

In some embodiments, the plurality of types of laser chips 103 in the laser device 10 correspond to the plurality of first electrode pins 1091, respectively, and two ends of any type of laser chips 103 are connected to a corresponding first electrode pin 1091 and a second electrode pin 1092, respectively, so that any type of laser chips 103 may receive the current through the first electrode pin 1091 and the second electrode pin 1092.

In some embodiments, there are a plurality of connection manners between the plurality of types of laser chips 103 and the plurality of conductive pins 109 in the laser device 10. The following is described by considering two of the plurality of connection manners as an example.

In the first connection manner between the laser chips 103 and the conductive pins 109, as shown in FIGS. 3 and 5, the at least one second electrode pin 1092 includes a plurality of second electrode pins 1092. The plurality of second electrode pins 1092 correspond to the plurality of types of laser chips 103, respectively, and the plurality of first electrode pins 1091 also correspond to the plurality of types of laser chips 103, respectively. In this way, any two types of laser chips 103 may be connected to different first electrode pins 1091 and different second electrode pins 1092. That is to say, the plurality of types of laser chips 103 do not share a conductive pin 109.

In some embodiments, the number of the first electrode pins 1091 and the number of the second electrode pins 1092 in the plurality of conductive pins 109 each are equal to the number of types of laser chips 103. That is to say, the number of the conductive pins 109 is twice the number of types of laser chips 103.

For example, as shown in FIG. 3, in a case where the two groups of laser chips 103 include three types of laser chips 103, the laser device 10 includes six conductive pins 109, and the six conductive pins 109 include three first electrode pins 1091 and three second electrode pins 1092.

For example, as shown in FIG. 5, in a case where the two groups of laser chips 103 include four types of laser chips 103, the laser device 10 includes eight conductive pins 109, and the eight conductive pins 109 include four first electrode pins 1091 and four second electrode pins 1092.

In some embodiments, the plurality of conductive pins 109 are disposed on three side walls of the frame 1012.

In some examples, as shown in FIGS. 3 and 5, in the two groups of laser chips 103, the first group of laser chips 103 includes the first type of laser chips 103A, and the second group of laser chips 103 includes at least two types of laser chips 103. The first group of laser chips 103 is disposed proximate to the fourth side wall 10125, and the second group of laser chips 103 is disposed proximate to the second side wall 10123. In this case, the plurality of conductive pins 109 are disposed on the first side wall 10122, the second side wall 10123, and the third side wall 10124. For example, the conductive pins 109 disposed on the first side wall 10122 or the third side wall 10124 are aligned with a corresponding type of laser chips 103 in the first direction Y. However, the present disclosure is not limited thereto, and the plurality of conductive pins 109 may also be disposed on four side walls of the frame 1012.

It will be noted that arrangement positions of the plurality of conductive pins 109 are related to arrangement positions of the plurality of types of laser chips 103 in the plurality of groups of laser chips 103, and the present disclosure does not limit the specific arrangement positions of the plurality of conductive pins 109.

As shown in FIG. 3, in a case where the second group of laser chips 103 includes the two types of laser chips 103B and 103C, first ends of the two types of laser chips 103B and 103C are disposed proximate to the first side wall 10122 and the third side wall 10124, respectively, and six conductive pins 109 are disposed on the first side wall 10122, the second side wall 10123, and the third side wall 10124.

For example, a first end of the first type of laser chips 103A is connected to the first conductive pin 109 disposed on the first side wall 10122, and a second end of the first type of laser chips 103A is connected to the first conductive pin 109 disposed on the third side wall 10124. The first end of the second type of laser chips 103B is connected to the second conductive pin 109 disposed on the first side wall 10122, and a second end of the second type of laser chips 103B is connected to the first conductive pin 109 disposed on the second side wall 10123. The first end of the third type of laser chips 103C is connected to the second conductive pin 109 disposed on the third side wall 10124, and a second end of the third type of laser chips 103C is connected to the second conductive pin 109 disposed on the second side wall 10123.

As shown in FIG. 5, in a case where the second group of laser chips 103 includes at least three types of laser chips 103, two ends of at least one type of laser chips 103 (e.g., the fourth type of laser chips 103D) in the second group of laser chips 103 are disposed away from the first side wall 10122 and the third side wall 10124. For example, the second group of laser chips 103 includes the three types of laser chips 103B, 103C, and 103D, and two of eight conductive pins 109 are disposed on the first side wall 10122, four of eight conductive pins 109 are disposed on the second side wall 10123, and two of eight conductive pins 109 are disposed on the third side wall 10124. Two ends of the fourth type of laser chips 103D are connected to two conductive pins 109 disposed on the second side wall 10123, respectively. Here, the connection manner between the conductive pin 109 and the second type of laser chips 103B or the third type of laser chips 103C is similar to that in FIG. 3, and details will not be repeated herein.

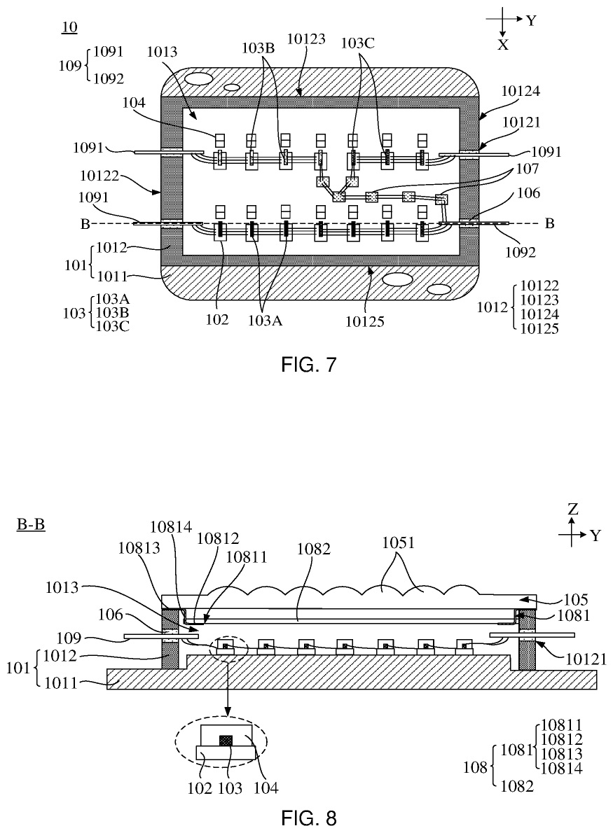

FIG. 7 is a top view of yet another laser device, in accordance with some embodiments. FIG. 4 may also be a sectional view of the laser device in FIG. 7 taken along the line B-B.

In the second connection manner between the laser chips 103 and the conductive pins 109, as shown in FIGS. 6 and 7, the plurality of first electrode pins 1091 are connected to the plurality of types of laser chips 103, respectively, and at least two types of laser chips 103 are connected to a same second electrode pin 1092. That is to say, the at least two types of laser chips 103 share one conductive pin 109 (e.g., the second electrode pin 1092).

It will be noted that, since different types of laser chips 103 require different currents to emit laser beams of different colors, different currents are required to be supplied to different types of laser chips 103, and different types of laser chips 103 are required to be connected to different first electrode pins 1091 or different second electrode pins 1092. For example, in a case where the plurality of types of laser chips 103 share a negative pin, the plurality of types of laser chips 103 may no longer share a positive pin.

In some embodiments, as shown in FIGS. 6 and 7, the plurality of conductive pins 109 are disposed on two opposite side walls of the frame 1012. For example, the plurality of conductive pins 109 are disposed on the first side wall 10122 and the third side wall 10124, however, the present disclosure is not limited thereto.

In some embodiments, as shown in FIGS. 6 and 7, the number of first electrode pins 1091 in the plurality of conductive pins 109 is equal to the number of types of laser chips 103 and greater than the number of second electrode pins 1092. That is to say, the number of conductive pins 109 is less than twice the number of types of the laser chips 103.

In some embodiments, in the plurality of groups of laser chips 103, at least two types of laser chips 103 in a same group of laser chips 103 may share a same second electrode pin 1092.

For example, as shown in FIG. 6, the laser device 10 includes five conductive pins 109, and the five conductive pins 109 include three first electrode pins 1091 and two second electrode pins 1092. Two of the three first electrode pins 1091 are disposed on the first side wall 10122, and one of the three first electrode pins 1091 is disposed on the third side wall 10124. The two second electrode pins 1092 are disposed on the third side wall 10124.

A first end of the first group of laser chips 103 (i.e., the first type of laser chips 103A) is connected to a first electrode pin 1091 disposed on the first side wall 10122, and a second end of the first group of laser chips 103 is connected to a second electrode pin 1092 disposed on the third side wall 10124. A first end (i.e., a first end of the second type of laser chips 103B) of the second group of laser chips 103 is connected to another first electrode pin 1091 disposed on the first side wall 10122, a second end (i.e., a first end of the third type of laser chips 103C) of the second group of laser chips 103 is connected to a first electrode pin 1091 disposed on the third side wall 10124, and a third end (i.e., an end where a second end of the second type of laser chips 103B and a second end of the third type of laser chips 103C are connected) of the second group of laser chips 103 is connected to another second electrode pin 1092 disposed on the third side wall 10124.

In some embodiments, in the plurality of groups of laser chips 103, the plurality of types of laser chips 103 may share a same second electrode pin 1092, so that the plurality of conductive pins 109 may include one second electrode pin 1092.

For example, as shown in FIG. 7, the laser device 10 includes four conductive pins 109, and the four conductive pins 109 include three first electrode pins 1091 and one second electrode pin 1092. Two of the three first electrode pins 1091 are disposed on the first side wall 10122, and one of the three first electrode pins 1091 is disposed on the third side wall 10124. The second electrode pin 1092 is disposed on the third side wall 10124.

The first end of the first group of laser chips 103 is connected to a first electrode pin 1091 disposed on the first side wall 10122, and the second end of the first group of laser chips 103 is connected to a second electrode pin 1092 disposed on the third side wall 10124. The first end of the second group of laser chips 103 is connected to another first electrode pin 1091 disposed on the first side wall 10122, the second end of the second group of laser chips 103 is connected to a first electrode pin 1091 disposed on the third side wall 10124, and the third end of the second group of laser chips 103 is connected to a same second electrode pin 1092 disposed on the third side wall 10124.

In some embodiments, as shown in FIG. 7, the number of conductive pins 109 is twice the number of groups of laser chips 103, and the plurality of conductive pins 109 are evenly distributed on two opposite side walls 10122 and 10124 of the frame 1012, however, the present disclosure is not limited thereto.

In the related art, since any conductive pin 005 is required to be fixed on the frame 0012 of the laser device 00 through an opening, the number of openings of the frame 0012 is at least twice the number of types of laser chips 003, resulting in a large volume of the laser device 00. For example, a base area of the tube shell 001 is equal to a product of 50 mm and 50 mm (i.e., 50 mm×50 mm).

However, in some embodiments of the present disclosure, since at least two types of laser chips 103 in at least one group of laser chips 103 are connected to a same conductive pin 109 (e.g., the second electrode pin 1092), the plurality of types of laser chips 103 may emit laser beams through a few conductive pins 109, so that the number of first openings 10121 is reduced. The reduction in the number of first openings 10121 reduces the possibility of the sealing insulator 106 falling off, so that the sealing effect of the frame 1012 is improved, thereby improving the reliability of the laser device 10. Moreover, by sharing a conductive pin 109, the type of laser chips 103 disposed in the tube shell 101 may be increased, which improves the versatility of the tube shell 101 and the light-emitting effect of the laser device 10. In addition, the reduction in the number of conductive pins 109 may also reduce the volume of the tube shell 101, so that the miniaturization of the laser device 10 may be achieved.

The laser device 10 provided in some embodiments of the present disclosure has a small volume. For example, a bottom surface of the tube shell 101 of the laser device 10 has a length within a range of 20 mm to 30 mm and a width within a range of 20 mm to 30 mm, inclusive. For example, the length of the bottom surface of the tube shell 101 is 20 mm, 23 mm, 25 mm, 28 mm, or 30 mm, and the width of the bottom surface of the tube shell 101 is 20 mm, 23 mm, 25 mm, 28 mm, or 30 mm. In this way, the base area of the tube shell 101 may be a product of 25 mm and 25 mm (i.e., 25 mm×25 mm).

In some embodiments, as shown in FIGS. 6 and 7, the laser device 10 further includes a plurality of connecting blocks 107 disposed on the substrate 1011. The plurality of connecting blocks 107 are configured to transfer wires. A surface of the connecting block 107 away from the substrate 1011 is conductive. In the plurality of groups of laser chips 103, at least two types of laser chips 103 that share a same conductive pin 109 (e.g., the second electrode pin 1092) are connected to a same conductive pin 109 through the plurality of connecting blocks 107. The plurality of connecting blocks 107 are connected with each other by wires, and the plurality of connecting blocks 107 are located between the common conductive pin 109 and the at least two types of laser chips 103.

In some embodiments, as shown in FIG. 6, the second type of laser chips 103B and the third type of laser chips 103C in the second group of laser chips 103 are connected to a same second electrode pin 1092 through the plurality of (e.g., six) connecting blocks 107. For example, after the second type of laser chips 103B and the third type of laser chips 103C each are connected to a connecting block 107, the two connecting blocks 107 connected with the two types of laser chips 103 are connected to a same connecting block 107. Then, the two connecting blocks 107 connected with the two types of laser chips 103 are connected in series to the remaining three connecting blocks 107 through the same connecting block 107, so that the two types of laser chips 103 may be connected to a same second electrode pin 1092.

In some embodiments, as shown in FIG. 7, the first group of laser chips 103 (i.e., the first type of laser chips 103A) and the two types of laser chips 103B and 103C in the second group of laser chips 103 are connected to a same second electrode pin 1092 through the plurality of connecting blocks 107. Such connection manner is similar to that in FIG. 6, and details will not be repeated herein.

In some embodiments, as shown in FIGS. 6 and 7, in the second direction X, the plurality of connecting blocks 107 are located between the two groups of laser chips 103.

It will be noted that in a case where two components required to be connected with each other cannot be directly connected through a wire, the connecting block 107 may be disposed between the two components, so that the wire may connect the two components through the connecting block 107.

The present disclosure does not limit the number and the positions of the connecting blocks 107, and the number and the positions of the connecting blocks 107 may be determined according to a distance between two components and an arrangement manner of the wire. In some embodiments, the number of connecting blocks 107 is less than a quantity threshold. The quantity threshold may be eight, nine, ten, or other values. The fewer the number of connecting blocks 107, the smaller the space occupied by the connecting blocks 107, which is conducive to reducing the volume of the laser device 10.

In some embodiments, the connecting block 107 includes a connecting body and a conductive portion, and the conductive portion is disposed on a side of the connecting body away from the substrate 1011.

In some embodiments, the connecting body is made of an insulating material, such as ceramic, aluminum nitride, or aluminum oxide. The conductive portion is made of gold or other conductive metals.

In some embodiments, the connecting block 107 has a columnar structure. For example, the connecting block 107 is in a shape of a cuboid, and the surface of the connecting block 107 away from the substrate 1011 is in a shape of a rectangle. A length of the rectangle is within a range of 0.5 mm to 1.5 mm, inclusive. For example, the length of the rectangle is 0.7 mm, 0.9 mm, 1.0 mm, 1.1 mm, 1.3 mm, or 1.5 mm. A width of the rectangle is within a range of 0.5 mm to 1.5 mm, inclusive. For example, the width of the rectangle is 0.5 mm, 0.7 mm, 0.8 mm, 0.9 mm, 1.1 mm, or 1.3 mm. However, the present disclosure is not limited thereto, and the connecting block 107 may also be in a shape of a cube, a cylinder, an elliptical cylinder, a prism, or other columnar structures.

It will be noted that if the length and width of the rectangular connecting block 107 are less than 0.5 mm, an area of the surface of the connecting block 107 away from the substrate 1011 is small, which affects the connection of the wires and has poor stability. If the length and width of the rectangular connecting block 107 are greater than 1.5 mm, the area of the surface of the connecting block 107 away from the substrate 1011 is large, which is not conducive to the miniaturization of the laser device 10. The present disclosure does not limit the size of the surface of the connecting block 107 away from the substrate 1011, and the size may be designed according to the arrangement requirements of the wires.

In some embodiments, the connecting block 107 and the laser chip 103 may be connected by using the wire bonding process. The connecting block 107 and the conductive pin 109 may be connected by using the wire bonding process. The plurality of laser chips 103 may be connected with each other by using the wire bonding process. The laser chip 103 and the conductive pin 109 may be connected by using the wire bonding process. For example, the wire is disposed between two components required to be connected with each other by using the wire bonding process, so as to make two ends of the wire be connected to the two components, respectively. For example, a wire bonding machine is used to press a wire onto a metal layer (e.g., a gold layer) on a surface of an object to be connected and heat a pad while providing pressure to the wire. As a result, a contact region between the wire and the gold layer becomes soft, so that the material of the wire may fuse with the material which the wire contacts, thereby achieving welding.

A strength of a wire is negatively related to a length of the wire, and the longer the length of the wire, the weaker the strength of the wire. Therefore, the distance between two components connected by a same wire is required to be less than or equal to a distance threshold. In this way, the strength of the wire connecting the two components may be improved, thereby improving the connection reliability of the two components.

In some embodiments, the distance between any two components connected by a same wire is less than or equal to 3 mm. That is to say, the distance threshold is 3 mm.

In some embodiments, the distance between the two components is within a range of 2 mm to 3 mm, inclusive. For example, the distance between the two components is 2 mm, 2.3 mm, 2.5 mm, 2.8 mm, or 3 mm.

In some examples, an interval between adjacent laser chips 103 in a same group of laser chips 103 is within a range of 1 mm to 3.5 mm, inclusive. For example, the interval between adjacent laser chips 103 in a same group of laser chips 103 is 1 mm, 1.5 mm, 2 mm, 2.5 mm, 3 mm, or 3.5 mm.

FIG. 8 is a sectional view of the laser device in FIG. 7 taken along the line B-B.

In some embodiments, as shown in FIG. 8, the laser device 10 further includes an upper cover assembly 108 covered on the tube shell 101. The upper cover assembly 108 is configured to seal the inner cavity of the tube shell 101. However, in some other embodiments, the upper cover assembly 108 may also be omitted.

The upper cover assembly 108 includes a cover plate 1081 and a light-transmitting layer 1082. The cover plate 1081 is disposed on the tube shell 101, and the light-transmitting layer 1082 is disposed on the cover plate 1081. In a case where the laser device 10 includes the collimating lens group 105, the collimating lens group 105 is disposed on a side of the cover plate 1081 away from the tube shell 101 and located on a side of the light-transmitting layer 1082 away from the substrate 1011. In this way, the cover plate 1081, the light-transmitting layer 1082, and the collimating lens group 105 may be arranged sequentially in a direction away from the substrate 1011. However, the present disclosure is not limited thereto. In some embodiments, the upper cover assembly 108 includes the cover plate 1081 but does not include the light-transmitting layer 1082; alternatively, the upper cover assembly 108 includes the light-transmitting layer 1082 but does not include the cover plate 1081.

The cover plate 1081 includes a second opening 10811. In a case where the cover plate 1081 is disposed on the tube shell 101, at least one heat sink 102, the plurality of groups of laser chips 103, and at least one prism 104 are exposed from the second opening 10811. In this case, the light-transmitting layer 1082 may cover the second opening 10811, so as to close the second opening 10811, thereby closing the inner cavity of the tube shell 101.

The cover plate 1081 further includes a first step 10812 and a second step 10813. The first step 10812 is at the same height as the second opening 10811. The second step 10813 is located on a side of the first step 10812 in the third direction Z and is disposed on the side of the frame 1012 away from the substrate 1011. The light-transmitting layer 1082 is disposed on a side of the first step 10812 away from the substrate 1011, so as to seal the second opening 10811.

The cover plate 1081 further includes a connecting plate 10814. The connecting plate 10814 is disposed perpendicularly to the first step 10812 and the second step 10813, and the connecting plate 10814 connects the first step 10812 and the second step 10813.

In some embodiments, the cover plate 1081 is made of stainless steel or kovar alloy. The kovar alloy may be an iron-nickel-cobalt alloy.

In some embodiments, the light-transmitting layer 1082 is made of glass or other transparent and high reliable material (e.g., resin).

In some embodiments, when the laser device 10 is assembled, the plurality of sealing insulators 106 are first covered on the plurality of conductive pins 109, and the conductive pins 109 covered by the sealing insulators 106 are inserted into the first openings 10121, so that the sealing insulators 106 are located in the first openings 10121. Then, the frame 1012 is placed on the substrate 1011 and a solder (e.g., silver-copper solder in a shape of a ring) is placed between the frame 1012 and the substrate 1011. The structure consisting of the substrate 1011, the frame 1012, and the conductive pins 109 is placed in a high-temperature furnace for sintering. The structure consisting of the substrate 1011, the frame 1012, and the conductive pins 109 is solidified to form the tube shell 101 after sintering, so that the airtightness at the first openings 10121 is achieved.

Next, the cover plate 1081 and the light-transmitting layer 1082 are fixedly connected with each other by using a sealing material, so as to obtain the upper cover assembly 108. The upper cover assembly 108 is soldered onto the surface of the frame 1012 away from the substrate 1011 by using the parallel gap seam welding technique after the at least one heat sink 102, the plurality of groups of laser chips 103, and the at least one prism 104 are soldered to corresponding positions of the substrate 1011. Finally, the collimating lens group 105 is fixed on the side of the upper cover assembly 108 away from the tube shell 101 by epoxy resin adhesive after the position of the collimating lens group 105 is aligned by using an alignment process, so that the assembly of the laser device 10 is completed.

It will be noted that the assembly process is an exemplary process provided in some embodiments of the present disclosure, and the soldering process used in each step in the assembly process may be replaced by other processes, and the sequence of the steps may also be adjusted correspondingly, and the present disclosure is not limited thereto.

In the laser device 10 provided in some embodiments of the present disclosure, the plurality of groups of laser chips 103 are disposed in the closed inner cavity formed by the tube shell 101 and the upper cover assembly 108, which may prevent the external water and oxygen from corroding the laser chips 103, so that the service life of the laser chips 103 is extended, thereby improving the light-emitting effect of the laser chips 103. Moreover, since there are a few first openings 10121 on the frame 1012, it is possible to improve the sealing effect of the frame 1012, so that the closed inner cavity of the laser device 10 may have a good sealing effect.

The above description is given by considering an example in which the laser device 10 includes one frame 1012. However, the present disclosure is not limited thereto. In some embodiments, the laser device 10 may further include a plurality of frames 1012.

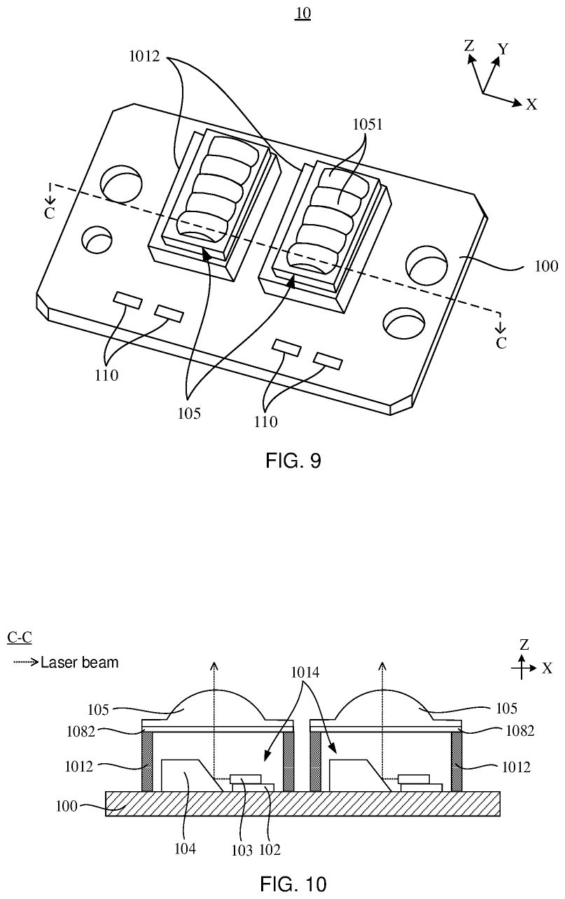

FIG. 9 is a diagram showing a structure of yet another laser device, in accordance with some embodiments. FIG. 10 is a sectional view of the laser device in FIG. 9 taken along the line C-C. FIG. 11 is a top view of the laser device in FIG. 9. It will be noted that FIG. 10 may also be a sectional view of the laser device in FIG. 11 taken along the line C-C.

In some embodiments, as shown in FIGS. 9 to 11, the laser device 10 includes a base 100 and a plurality of frames 1012. The plurality of frames 1012 are disposed on the base 100, and a group of laser chips 103 is correspondingly disposed in any frame 1012.

In this case, the laser device 10 further includes a plurality of collimating lens groups 105, and the plurality of collimating lens groups 105 correspond to the plurality of groups of laser chips 103, respectively. Any collimating lens group 105 is located on a side of a corresponding group of laser chips 103 away from the base 100. Any collimating lens group 105 includes a plurality of collimating lenses 1051, and the plurality of collimating lenses 1051 correspond to a plurality of laser chips 103 in the corresponding frame 1012, respectively.

In some embodiments, an orthogonal projection of the collimating lens 1051 on the base 100 overlaps with an orthogonal projection of the corresponding laser chip 103 on the base 100.

It will be noted that the present disclosure does not limit the number of frames 1012 and the number of collimating lens groups 105. The number of frames 1012 and the number of collimating lens groups 105 may be two, three, four, or more. For example, as shown in FIGS. 9 and 10, in a case where the number of groups of laser chips 103 is two, the number of frames 1012 is two, and the number of collimating lens groups 105 is two. Alternatively, as shown in FIG. 12, in a case where the number of groups of laser chips 103 is three, the number of frames 1012 is three, and the number of collimating lens groups 105 is three. Here, FIG. 12 is a top view of yet another laser device, in accordance with some embodiments.

In some embodiments, the plurality of collimating lenses 1051 in the collimating lens group 105 may be a one-piece member. For example, the collimating lens group 105 is substantially in a shape of a plate, and a surface of the collimating lens group 105 proximate to the base 100 is a plane, and a surface of the collimating lens group 105 away from the base 100 has a plurality of convex arc surfaces, and a portion where any of the plurality of convex arc surfaces is located is a collimating lens 1051.

It will be noted that the plurality of collimating lenses 1051 in the collimating lens group 105 may be formed according to a preset size and interval. The plurality of laser chips 103 in the laser device 10 may also be mounted at positions matching the collimating lenses 1051. There may be mounting errors during the mounting process of the laser chips 103, and there is a deviation between an actual mounting position and a preset mounting position. Therefore, when the collimating lens group 105 is assembled, the plurality of collimating lenses 1051 in the collimating lens group 105 each are required to be aligned with a corresponding laser chip 103, so that the laser beam emitted by the laser chip 103 may be incident on the corresponding collimating lens 1051 as far as possible.

In the laser device 10 provided in some embodiments of the present disclosure, firstly, the plurality of groups of laser chips 103 are disposed in the inner cavities 1014 of the plurality of frames 1012. Then, a corresponding collimating lens group 105 is used to collimate laser beams emitted by any group of laser chips 103. In this way, it is only necessary to align the collimating lens group 105 corresponding to the group of laser chips 103. In this case, even if there is an error in the mounting position of a group of laser chips 103, the error will not affect the collimating effect of other groups of laser chips 103.

Moreover, since the plurality of groups of laser chips 103 are disposed in the inner cavities 1014 of the plurality of frames 1012, respectively, there are a few laser chips 103 in any frame 1012. In this way, any collimating lens group 105 corresponds to a small number of laser chips 103, which may improve the aligning effect between the plurality of collimating lenses 1051 in the collimating lens group 105 and the corresponding laser chips 103. As a result, a lot of laser beams emitted by the plurality of laser chips 103 may be incident on the corresponding collimating lenses 1051, and the collimating lens group 105 may collimate the laser beams emitted by the plurality of laser chips 103 well, thereby improving the collimating degree of the laser beams emitted by the laser device 10.

In some embodiments, the frame 1012 may be fixed to the base 100 by a brazing process.

It will be noted that if the plurality of frames 1012 are brazed at the same time, high heat may be generated during the brazing process, which causes thermal stress between the frame 1012 and the base 100. If the thermal stress is large, the frame 1012 and the base 100 may be damaged.

Therefore, in some embodiments, the plurality of frames 1012 may be fixed to the base 100 by soldering at different moments. For example, one frame 1012 is first soldered to the base 100, and then the frame 1012 and the base 100 are cooled after the frame 1012 has been soldered. Next, another frame 1012 is soldered on the base 100, and then the frame 1012 and the base 100 are cooled after the frame 1012 has been soldered. Such cycle is repeated until the fixing between the frame 1012 and the base 100 is complete.

Since the frame 1012 has a small volume, a contact area between the frame 1012 and the base 100 is small. Since the thermal stress between two objects during soldering is positively related to a contact area between the two objects, in a case where the plurality of frames 1012 are soldered on the base 100 at different moment, there is small thermal stress generated during each soldering. Moreover, when a next frame 1012 is soldered after a previous frame 1012 has been soldered, the thermal stress generated between the previous frame 1012 and the base 100 may be basically released, so that the risk of damage to the frame 1012 and the base 100 due to the thermal stress during soldering may be reduced.

Moreover, in the laser device 10 provided in some embodiments of the present disclosure, the laser device 10 may be modularized by providing the plurality of independent frames 1012 and providing the laser chips 103 in the plurality of frames 1012, so that a portion where any frame 1012 is located is equivalent to a small laser device. In this way, the structure of the laser device 10 may be flexibly changed, and the structure of the laser device 10 may be flexibly adjusted in different application scenarios, which improves the flexibility of use of the laser device 10.

In some embodiments, as shown in FIG. 10, the laser device 10 further includes a plurality of light-transmitting layers 1082. The plurality of light-transmitting layers 1082 correspond to the plurality of frames 1012, respectively. The light-transmitting layer 1082 is located on a side of the corresponding frame 1012 away from the base 100 and configured to seal the inner cavity 1014 of the corresponding frame 1012.

In some embodiments, the plurality of frames 1012 each has a structure in a shape of a square ring, and an orthogonal projection of the frame 1012 on the base 100 is in a shape of a square ring or a quasi-square ring.

In some embodiments, as shown in FIG. 9, the plurality of frames 1012 may be arranged sequentially in the second direction X. The second direction X may be a width direction of the frame 1012 or the fast axis direction of the laser beams exiting from the frame 1012.

For example, an arrangement direction of the plurality of frames 1012 is parallel to the fast axis direction of the laser beams exiting from the frame 1012. In a case where the plurality of laser chips 103 in the frame 1012 are arranged in the slow axis direction of the laser beams, a size of a beam spot formed by the laser beams emitted by the plurality of laser chips 103 after the laser beams exit from the frame 1012 is greater than a size of the beam spot in the slow axis direction. In this case, by arranging the plurality of frames 1012 in the fast axis direction, a difference between the size of the beam spot in the slow axis direction and the size of the beam spot in the fast axis direction may be reduced, so that the symmetry of the beam spot may be improved.

In addition, an overall shape of the laser device 10 may be regular, which is conducive to storage, transportation and use.

In some embodiments, the plurality of frames 1012 may further be arranged sequentially in the first direction Y, and the present disclosure is not limited thereto. For example, in a case where the width direction of the frame 1012 is the first direction Y and the length direction of the frame 1012 is the second direction X, the plurality of frames 1012 are arranged in sequence in the first direction Y.

In some embodiments, at least one of the plurality of groups of laser chips 103 includes at least two types of laser chips 103.

As shown in FIG. 11, the laser device 10 includes two groups of laser chips 103, and the two groups of laser chips 103 are a first group of laser chips 103 and a second group of laser chips 103, respectively. Compared with FIGS. 3, 6, and 7, the two groups of laser chips 103 (i.e., three types of laser chips 103) in FIG. 11 are disposed in the inner cavities 1014 of different frames 1012 and correspond to different collimating lens groups 105.

For example, as shown in FIG. 11, the laser device 10 includes two frames 1012 and two collimating lens groups 105. The first group of laser chips 103 (i.e., the first type of laser chips 103A) is disposed in the inner cavity 1014 of a first frame 1012, and the second group of laser chips 103 (i.e., the second type of laser chips 103B and the third type of laser chips 103C) is disposed in the inner cavity 1014 of a second frame 1012. The first group of laser chips 103 and the second group of laser chips 103 each include five laser chips 103. Correspondingly, the two collimating lens groups 105 each further include five collimating lenses 1051.

In some embodiments, the plurality of laser chips 103 in any group of laser chips emit laser beams of a same color. That is to say, any group of laser chips 103 includes one type of laser chips 103.

As shown in FIG. 12, the laser device 10 includes three groups of laser chips 103, and the three groups of laser chips 103 are a first group of laser chips 103, a second group of laser chips 103, and a third group of laser chips 103, respectively. The first group of laser chips 103 includes the first type of laser chips 103A, the second group of laser chips 103 includes the second type of laser chips 103B, and the third group of laser chips 103 includes the third type of laser chips 103C. Compared with FIGS. 3, 6, and 7, the three groups of laser chips 103 (i.e., three types of laser chips 103) in FIG. 12 are disposed in the inner cavities 1014 of different frames 1012 and correspond to different collimating lens groups 105.

For example, as shown in FIG. 12, the laser device 10 includes three frames 1012 and three collimating lens groups 105. The first group of laser chips 103 (i.e., the first type of laser chips 103A) is disposed in the inner cavity 1014 of the first frame 1012, the second group of laser chips 103 (i.e., the second type of laser chips 103B) is disposed in the inner cavity 1014 of the second frame 1012, and the third group of laser chips 103 (i.e., the third type of laser chips 103C) is disposed in the inner cavity 1014 of the third frame 1012.

The number of the laser chips 103 in the first group of laser chips 103 is five, the number of the laser chips 103 in the second group of laser chips 103 is four, and the number of the laser chips 103 in the third group of laser chips 103 is three. Correspondingly, the numbers of the collimating lenses 1051 in the three collimating lens groups 105 are five, four, and three, respectively. The number of the first type of laser chips 103A is greater than the number of the second type of laser chips 103B and the number of the third type of laser chips 103C, and less than the sum of the number of the second type of laser chips 103B and the number of the third type of laser chips 103C. The number of the second type of laser chips 103B is greater than the number of the third type of laser chips 103C.

In some embodiments, as shown in FIGS. 9, 11, and 12, the laser device 10 includes a plurality of conductive regions 110. The plurality of conductive regions 110 are disposed on the base 100 and located in a region outside the plurality of frames 1012.

The plurality of conductive regions 110 are electrically connected to the external power supply and configured to transmit currents to the components (e.g., the plurality of groups of laser chips 103) connected thereof. The plurality of conductive regions 110 include a plurality of first conductive regions 1101 and at least one second conductive region 1102. The first conductive region 1101 and the second conductive region 1102 are connected to opposite electrodes of the external power supply. For example, the first conductive region 1101 is connected to the positive electrode of the external power supply, and the second conductive region 1102 is connected to the negative electrode of the external power supply; alternatively, the first conductive region 1101 is connected to the negative electrode of the external power supply, and the second conductive region 1102 is connected to the positive electrode of the external power supply.

Any laser chip 103 is connected to one first conductive region 1101 and one second conductive region 1102. In this way, the external power supply may be electrically connected to the plurality of groups of laser chips 103 through the plurality of conductive regions 110, so as to achieve current transmission to the plurality of groups of laser chips 103. It will be noted that the connection manner of the plurality of conductive regions 110 and the plurality of groups of laser chips 103 is similar to the connection manner of the plurality of conductive pins 109 and the plurality of groups of laser chips 103.

In some embodiments, the plurality of conductive regions 110 may be located on a same side of the plurality of frames 1012. In this way, it is conducive to supplying currents to the laser chips 103 in the plurality of frames 1012 and also conducive to the arrangement of the plurality of frames 1012 and the corresponding plurality of groups of laser chips 103.

In some embodiments, as shown in FIGS. 11 and 12, the plurality of groups of laser chips 103 are connected to different first conductive regions 1101, and at least two groups of laser chips 103 are connected to a same second conductive region 1102. That is to say, the at least two groups of laser chips 103 share a second conductive region 1102.

For example, as shown in FIGS. 11 and 12, the laser device 10 includes four conductive regions 110. The four conductive regions 110 are arranged in sequence in the second direction X and located on a same side of the plurality of frames 1012 in the first direction Y. The four conductive regions 110 include three first conductive regions 1101 and one second conductive region 1102. The three first conductive regions 1101 are connected to a first end of the first group of laser chips 103, a first end of the second group of laser chips 103, and a first end of the third group of laser chips 103, respectively. A second end of the first group of laser chips 103, a second end of the second group of laser chips 103, and a second end of the third group of laser chips 103 are connected to a same second conductive region 1102, so that currents may be transmitted to the plurality of groups of laser chips 103.

In some embodiments, the laser device 10 further includes a plurality of power supply terminals 1010. The plurality of power supply terminals 1010 correspond to the plurality of first openings 10121, respectively, and the plurality of power supply terminals 1010 are connected to the plurality of conductive regions 110. The plurality of power supply terminals 1010 are configured to connect a component (e.g., the laser chips 103) inside the frame 1012 with a component (e.g., the conductive regions 110) outside the frame 1012.

Any frame 1012 includes at least two first openings 10121, and the power supply terminal 1010 is inserted into the frame 1012 through the corresponding first opening 10121. The power supply terminal 1010 includes three sections, and the three sections are a first section, a second section, and a third section connected in sequence. The first section is a portion of the power supply terminal 1010 located outside of the frame 1012, the second section is a portion of the power supply terminal 1010 located in the corresponding first opening 10121, and the third section is a portion of the power supply terminal 1010 that passes through the corresponding first opening 10121 and extends into the inner side of the frame 1012.

The first section of the power supply terminal 1010 is connected to the corresponding conductive region 110, so as to be connected to an electrode (e.g., the positive electrode or the negative electrode) of the external power supply. The third section of the power supply terminal 1010 is connected to an electrode (e.g., the first electrode or the second electrode) of the corresponding laser chip 103 through wires. In this way, the external power supply may transmit currents to the plurality of groups of laser chips 103 through the plurality of power supply terminals 1010 and the plurality of conductive regions 110.

Any type of laser chips 103 in any group of laser chips 103 may correspond to two power supply terminals 1010. One power supply terminal 1010 is connected to the first conductive region 1101, and another power supply terminal 1010 is connected to the second conductive region 1102. Two ends of the type of laser chips 103 are connected to the two power supply terminals 1010, respectively. Here, the power supply terminal 1010 connected to the first conductive region 1101 in the plurality of power supply terminals 1010 may be referred to as a first portion of the power supply terminals 1010, and the power supply terminal 1010 connected to the second conductive region 1102 in the plurality of power supply terminals 1010 may be referred to as a second portion of the power supply terminals 1010.

In some embodiments, in a case where the plurality of types of laser chips 103 in a group of laser chips 103 share a second conductive region 1102, the plurality of types of laser chips 103 may also share a power supply terminal 1010, and the power supply terminal 1010 is connected to the common conductive region 110.

For example, as shown in FIG. 11, the first group of laser chips 103 includes the first type of laser chips 103A, and two power supply terminals 1010 are fixed on the frame 1012 corresponding to the first group of laser chips 103. One of the two power supply terminals 1010 is connected to the first conductive region 1101 corresponding to the first group of laser chips 103, and another of the two power supply terminals 1010 is connected to the second conductive region 1102 shared by the plurality of groups of laser chips 103.

The second group of laser chips 103 includes the two types of laser chips 103B and 103C. Three power supply terminals 1010 are fixed on the frame 1012 corresponding to the second group of laser chips 103. First ends of the two types of laser chips 103B and 103C are connected to two of the three power supply terminals 1010, respectively, and second ends of the two types of laser chips 103B and 103C are connected to a remaining one of the three power supply terminals 1010. The two types of laser chips 103B and 103C share a power supply terminal 1010, and the shared power supply terminal 1010 is connected to the second conductive region 1102 shared by the plurality of groups of laser chips 103.

For another example, as shown in FIG. 12, in a case where any group of laser chips 103 includes one type of laser chips 103, and the type of the laser chips 103 are connected in series, two power supply terminals 1010 are fixed on any frame 1012. One of the two power supply terminals 1010 is connected to the first conductive region 1101 corresponding to the corresponding group of laser chips 103, and another of the two power supply terminals 1010 is connected to the second conductive region 1102 shared by the plurality of groups of laser chips 103.

In some embodiments, different types of laser chips 103 in a same group of laser chips 103 that share a same conductive region 110 may also be connected to different power supply terminals 1010. For example, ends of the second type of laser chips 103B and the third type of laser chips 103C in FIG. 11 that are proximate to each other may also be connected to two different power supply terminals 1010, respectively.

In some embodiments, the plurality of power supply terminals 1010 are connected to the plurality of conductive regions 110 through the base 100. For example, the laser device 10 further includes a transmitting circuit, and the transmitting circuit is embedded in the base 100. The transmitting circuit is configured to connect the power supply terminal 1010 and the corresponding conductive region 110. In this case, the base 100 may include a printed circuit board (PCB), so that the power supply terminals 1010 are connected to the conductive regions 110.

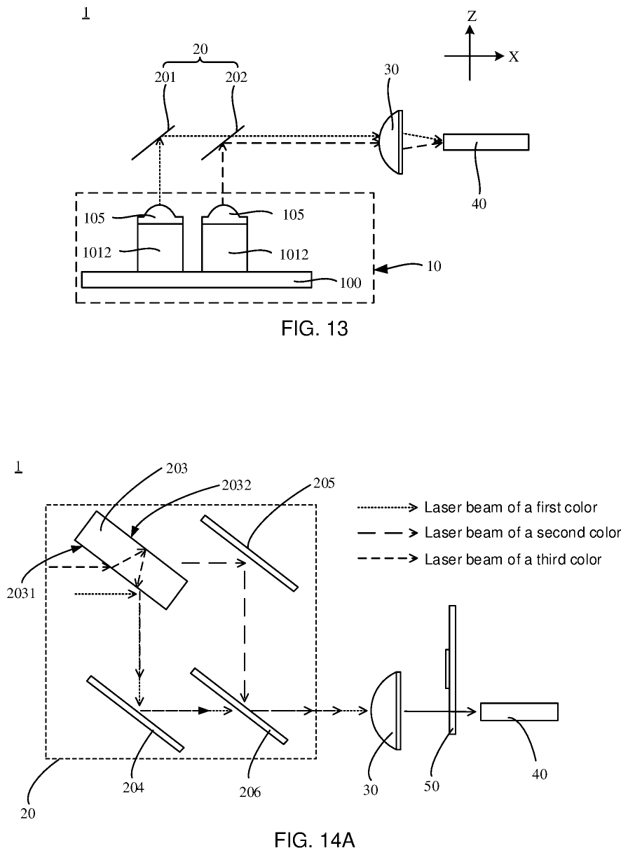

FIG. 13 is a diagram showing a structure of a laser source assembly, in accordance with some embodiments.

In some embodiments of the present disclosure, a laser source assembly 1 is further provided. As shown in FIG. 13, the laser source assembly 1 includes a laser device 10, a combining lens group 20, a converging lens 30, and a light homogenizing component 40. The combining lens group 20, the converging lens 30, and the light homogenizing component 40 are arranged in sequence in a target direction (e.g., the second direction X).

For relevant contents of the laser device 10, reference may be made to the relevant contents described above, and details will not be repeated herein.

The laser beams exiting from the laser device 10 are incident on the combining lens group 20. The combining lens group 20 is located on a laser-exit side of the laser device 10. The combining lens group 20 is configured to receive laser beams of a plurality of colors emitted by the laser device 10, combine the laser beams of the plurality of colors, and propagate the combined laser beam in the target direction.

The laser beam exiting from the combining lens group 20 is incident on the converging lens 30. The converging lens 30 is configured to receive the combined laser beam, converge the combined laser beam, and propagate the laser beam in the target direction.

The laser beam exiting from the converging lens 30 is incident on the light homogenizing component 40. The light homogenizing component 40 is configured to increase a divergence angle of the combined laser beam in at least one of the fast axis direction or the slow axis direction, so as to homogenize the combined laser beam.

The laser beam exiting from the light homogenizing component 40 may be used for subsequent image projection of a laser projection apparatus, so as to form a projection image.

In some embodiments, the light homogenizing component 40 is a light pipe, or other components (e.g., a fly-eye lens) for homogenizing light. For example, as shown in FIG. 13, the light homogenizing component 40 is a light pipe. Alternatively, as shown in FIG. 15, the light homogenizing component 40 is a fly-eye lens.

In some embodiments, the combining lens group 20 includes at least one combining lens arranged sequentially in the target direction. The at least one combining lens is located on a side of the collimating lens group 105 away from the base 100 and oblique with respect to a laser-exit direction of the laser device 10.

In some embodiments, the at least one combining lens includes a plurality of combining lenses. In a case where the laser device 10 includes the plurality of collimating lens groups 105, the plurality of combining lenses may correspond to the plurality of collimating lens groups 105, respectively. An orthogonal projection of the combining lens on the base 100 may overlap with an orthogonal projection of the corresponding collimating lens group 105 on the base 100.

It will be noted that the present disclosure does not limit the type of combining lenses in the combining lens group 20.

In some embodiments, the combining lens farthest from the converging lens 30 in the plurality of combining lenses may be a reflecting lens for the full spectrum, and a remaining combining lens in the plurality of combining lenses may be a dichroic mirror. The dichroic mirror is configured to reflect the laser beam incident on the dichroic mirror from the laser device 10 and transmit the laser beam exiting from the combining lens located on a side of the dichroic mirror away from the converging lens 30. In some embodiments, the plurality of the combining lenses are dichroic mirrors.

For example, as shown in FIG. 13, the combining lens group 20 includes a first reflecting lens 201 and a first dichroic mirror 202, so as to combine the laser beams emitted by the laser chips 103 in the two frames 1012 of the laser device 10. The laser beams exiting from the two frames 1012 may be laser beams of three colors. For the arrangement of the laser chips 103 in the two frames 1012, reference may be made to related contents described above.

The first reflecting lens 201 is disposed obliquely with respect to the laser-exit direction of the laser device 10 and configured to reflect a laser beam of at least one color of the laser beams of a plurality of colors. The first dichroic mirror 202 is disposed obliquely with respect to the laser-exit direction of the laser device 10, and located on a laser-exit side of the first reflecting lens 201, and disposed proximate to the converging lens 30. The first dichroic mirror 202 is configured to transmit the laser beam of the at least one color and reflect the laser beam of a remaining color in the laser beams of the plurality of colors. In this way, the first reflecting lens 201 reflects the laser beam emitted to the first reflecting lens 201 by the laser device 10 to the first dichroic mirror 202. The first dichroic mirror 202 reflects the laser beam emitted to the first dichroic mirror 202 by the laser device 10 to the converging lens 30 and transmits the laser beam exiting from the first reflecting lens 201 to the first dichroic mirror 202 to the converging lens 30.

In some embodiments, the first reflecting lens 201 is disposed corresponding to the laser chips 103 in the first of the two frames 1012. The laser chips 103 in the first frame 1012 may emit laser beams of two colors, such as the blue laser beam and the green laser beam. The first dichroic mirror 202 is disposed corresponding to the laser chips 103 in the second of the two frames 1012. The laser chips 103 in the second frame 1012 may emit a laser beam of one color, such as the red laser beam.

In some embodiments, the first dichroic mirror 202 may combine laser beams according to a wavelength. For example, the first dichroic mirror 202 transmits the blue laser beam and the green laser beam and reflects the red laser beam.

In some other embodiments, the first dichroic mirror 202 may combine laser beams according to a polarization direction. For example, the blue laser beam and the green laser beam have a same polarization direction, and the polarization directions of the blue laser beam and the green laser beam are different from a polarization direction of the red laser beam. Generally, the polarization direction of the blue laser beam or the green laser beam and the polarization direction of the red laser beam are different by 90°. In this case, the first dichroic mirror 202 may transmit the laser beams (e.g., the blue laser beam and the green laser beam) with a polarization direction and reflect the laser beams (e.g., the red laser beam) with another polarization direction.

Of course, the combining lens group 20 may also include other structures.

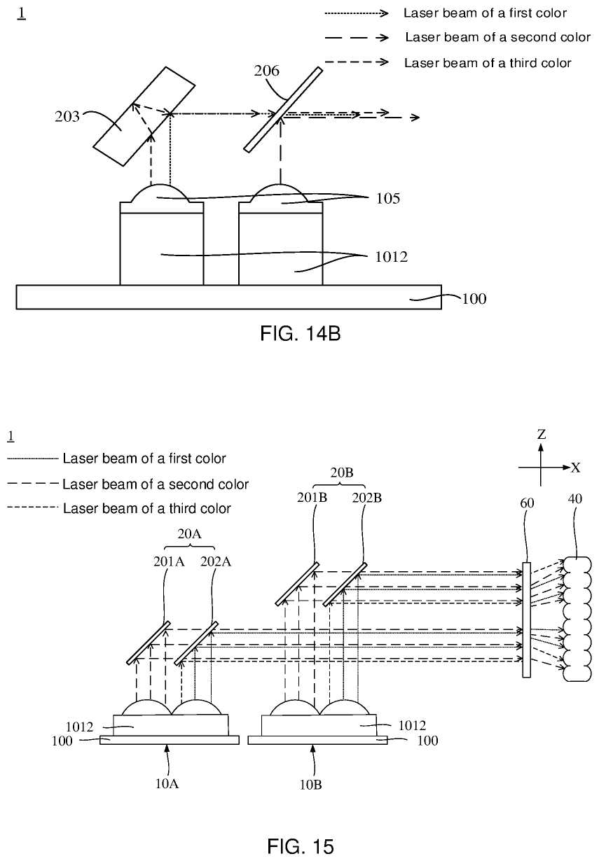

FIG. 14A is a diagram showing a principle of a beam path of a laser source assembly, in accordance with some embodiments. In FIG. 14A, dashed arrows of different types represent laser beams of different colors.

In some embodiments, as shown in FIG. 14A, the combining lens group 20 includes a combining prism 203, a second reflecting lens 204, a third reflecting lens 205, and a second dichroic mirror 206, so as to combine the laser beams emitted by the laser chips 103 in the two frames 1012 of the laser device 10. The laser beams exiting from the two frames 1012 may be laser beams of three colors. For the arrangement of the laser chips 103 in the two frames 1012, reference may be made to related contents described above.

The combining prism 203 is located on a laser-exit side of the laser chips 103 in the first frame 1012 of the two frames 1012 and includes a first surface 2031 and a second surface 2032 that are disposed opposite to each other. The first surface 2031 is configured to reflect a laser beam of a first color, transmit a laser beam of a third color, and refract the laser beam of the third color. The laser beam of the third color is refracted by the first surface 2031, so that the laser beam of the third color is transmitted into the combining prism 203. The second surface 2032 is configured to reflect the laser beam of the third color to the first surface 2031. The reflected laser beam of the third color is refracted again by the first surface 2031 and exits from the combining prism 203. The combining prism 203 has a preset thickness. Beam spots of the laser beam of the first color and the laser beam of the third color may be overlapped with each other by adjusting the thickness of the combining prism 203.

For example, as shown in FIG. 14A, the laser beam of the third color enters into the combining prism 203 after being refracted by the first surface 2031. Inside the combining prism 203, the refracted laser beam of the third color is reflected to the first surface 2031 by the second surface 2032 and exits from the combining prism 203 after being refracted again by the first surface 2031. Since the combining prism 203 has the preset thickness, the laser beam of the third color may propagate for a distance inside the combining prism 203 after the first refraction and then be incident on the second surface 2032. Therefore, compared with an intersection between a normal line of the first surface 2031 corresponding to the laser beam of the third color and the second surface 2032, a position of the beam spot of the laser beam of the third color on the second surface 2032 is shifted.

Moreover, when the laser beam of the third color is reflected by the second surface 2032 and incident on the first surface 2031 again, compared with an initial position of the beam spot of the laser beam of the third color on the first surface 2031, the position of the beam spot of the laser beam of the third color on the first surface 2031 is shifted after passing through the combining prism 203. In this way, the position of the beam spot of the laser beam of the third color on the first surface 2031 may overlap with the position of the beam spot of the laser beam of the first color on the first surface 2031 after the laser beam of the third color is refracted twice and reflected once by the combining prism 203. As a result, the coincidence of the beam pots of the laser beams of the first color and the third color is achieved, which improves the overlap of the beam spot formed by combining the laser beams of the two colors, thereby reducing a size of the beam spot formed by combining the laser beams of the first color and the third color.

The laser beams of the first color and the third color exiting from the combining prism 203 are incident on the second reflecting lens 204. The second reflecting lens 204 is located on a laser-exit side of the combining prism 203 and configured to reflect the laser beams of the first color and the third color.

A laser beam of a second color emitted by the laser chips 103 in the second frame 1012 of the two frames 1012 is incident on the third reflecting lens 205. The third reflecting lens 205 is configured to reflect the laser beam of the second color.

The second dichroic mirror 206 is located on laser-exit sides of the second reflecting lens 204 and the third reflecting lens 205 and configured to transmit the laser beams of the first color and the third color and reflect the laser beam of the second color. For example, the second dichroic mirror 206 is located at an intersection of a laser-exit path of the second reflecting lens 204 and a laser-exit path of the third reflecting lens 205.

In this way, the combination of laser beams of the plurality of colors may be achieved after the laser beams of the first color and the third color are reflected by the second reflecting lens 204 and transmitted by the second dichroic mirror 206 and after the laser beam of the second color is reflected by the third reflecting lens 205 and the second dichroic mirror 206.

In some embodiments, the combining lens group 20 may also omit the second reflecting lens 204 and the third reflecting lens 205. For example, as shown in FIG. 14B, the combining lens group 20 includes a combining prism 203 and a second dichroic mirror 206.

For the structure and function of the combining prism 203, reference may be made to the related description of FIG. 14A.

The second dichroic mirror 206 is located on a laser-exit side of the combining prism 203 and a laser-exit side of the laser chips 103 in the second frame 1012 of the two frames 1012. The second dichroic mirror 206 is configured to transmit the laser beams of the first color and the third color and reflect the laser beam of the second color. In this way, the laser beams of the first color, the second color, and the third color are combined by the second dichroic mirror 206 after the laser beams of the first color and the third color are combined by the combining prism 203 and after the laser beam of the second color emitted by the laser chips 103 in the second frame 1012 of the two frames 1012 is incident on the second dichroic mirror 206.

For ease of description, the combination of the second reflecting lens 204, the third reflecting lens 205, and the second dichroic mirror 206 in FIG. 14A, or the second dichroic mirror 206 in FIG. 14B may be referred to as a combining lens sub-group.

In some embodiments, as shown in FIG. 14A, the converging lens 30 is located on a laser-exit side of the combining lens group 20, so as to compress the divergence angle of the combined laser beam.

In some embodiments, as shown in FIG. 14A, the laser source assembly 1 further includes a first diffusion component 50. The first diffusion component 50 is located between the converging lens 30 and the light homogenizing component 40. The first diffusion component 50 is configured to receive the combined laser beam and diffuse the combined laser beam, so as to reduce or eliminate a speckle effect. The first diffusion component 50 is capable of vibrating or rotating. For example, the first diffusion component 50 includes a diffusion wheel, and the diffusion wheel is rotatable.

In some embodiments, another light homogenizing component or another diffusion component may also be disposed between the converging lens 30 and the first diffusion component 50. For example, a diffusion plate or a fly-eye lens is fixedly disposed between the converging lens 30 and the first diffusion component 50. The speckle effect may be further reduced or eliminated by the cooperation of the fixed diffusion plate and the rotating first diffusion component.

FIG. 15 is a diagram showing a principle of a beam path of yet another laser source assembly, in accordance with some embodiments of the present disclosure.

In some embodiments, the laser source assembly 1 may include a plurality of laser devices 10, and any laser device 10 may include a plurality of frames 1012.

As shown in FIG. 15, the laser source assembly 1 includes two laser devices 10A and 10B. The laser device 10A and the laser device 10B each may include two frames 1012, and the laser beams exiting from the two frames 1012 have different colors. The laser beams emitted by the laser device 10A or 10B are the laser beams of three colors.

The laser source assembly 1 further includes two combining lens groups 20A and 20B. The combining lens group 20A includes a first reflecting lens 201A and a first dichroic mirror 202A, and the combining lens group 20B includes a first reflecting lens 201B and a first dichroic mirror 202B. For the relevant content of the two combining lens groups 20A and 20B, reference may be made to the relevant content in FIG. 13, and details will not be repeated herein. The laser beams emitted by the laser device 10A are combined by the first reflecting lens 201A and the first dichroic mirror 202A, and the laser beams emitted by the laser device 10B are combined by the first reflecting lens 201B and the first dichroic mirror 202B. Output beam paths of the combined laser beams of the two laser devices 10A and 10B are separated from (i.e., do not overlap with) each other, but the two output beam paths are proximate to each other, so as to reduce a gap between the two combined beam spots.

The laser source assembly 1 further includes a second diffusion component 60. The combined beam spots output by the laser device 10A and the laser device 10B are incident on the second diffusion component 60. The second diffusion component 60 may be a diffusion plate capable of vibrating or rotating. The second diffusion component 60 may diffuse the combined beam spot of the laser beams of three colors, so as to increase Etendue, thereby reducing the speckle effect of the laser beams.

The beam diffused and output by the second diffusion component 60 is incident on the light homogenizing component 40. The light homogenizing component 40 may be a fly-eye lens to homogenize the incident beam spot, so that the uniformity of the beam is improved. In the laser source assembly 1 shown in FIG. 15, the combined beam spot of the laser beams of three colors may be incident on the second diffusion component 60 with an original size. Since the diffusion effect is positively related to the size of the beam spot, the second diffusion component 60 has a good diffusion effect in a case where the second diffusion component 60 directly receives an original combined beam spot. Here, the original size of the combined beam spot of the laser beams of three colors may be understood as the combined beam of the laser beams of three colors without being contracted by a corresponding beam contraction lens group.

Moreover, the size of the beam spot diffused by the second diffusion component 60 is increased. In this way, compared with the light pipe in the laser source assembly 1 in FIG. 13, the fly-eye lens is more suitable for receiving a large-sized beam spot for homogenization. The light pipe is suitable for receiving a beam spot with a large angle and a small size.

In some embodiments, the laser source assembly 1 may further include a beam contraction lens group. The beam contraction lens group is disposed on a laser-incident side of the second diffusion component 60 and configured to contract the combined beam. In this way, the size of the combined beam spot may be reduced after the combined beam spot is contracted, thereby reducing a laser-receiving area of the second diffusion component 60 and reducing the size of the second diffusion component 60.

In some embodiments, the laser source assembly 1 may further include a lens disposed between the second diffusion component 60 and the light homogenizing component 40, so as to compress a divergence angle of the beam diffused by the second diffusion component 60. As a result, the beam may be incident on the light homogenizing component 40 as a parallel beam, thereby improving the light homogenizing effect of the light homogenizing component 40.

In the laser source assembly 1 provided in some embodiments of the present disclosure, since the laser beam emitted by the laser device 10 has a good collimating degree, the laser source assembly 1 may have a good illumination effect in a case where the laser source assembly 1 adjusts the beam based on the laser beam with a good collimating degree. In this way, when the laser projection apparatus projects an image based on the laser beam emitted by the laser source assembly 1, the projection image has a good display effect, thereby improving the display effect of the laser projection apparatus where the laser source assembly 1 is located.

In the above description of the embodiments, specific features, structures, materials, or characteristics may be combined in a suitable manner in any one or more embodiments or examples.

A person skilled in the art will understand that the scope of disclosure in the present disclosure is not limited to specific embodiments discussed above and may modify and substitute some elements of the embodiments without departing from the spirits of the present disclosure. The scope of the present disclosure is limited by the appended claims.

What is claimed is:

1. A laser device, comprising:
a base;
a plurality of frames disposed on the base;
a plurality of groups of laser chips disposed on the base, any of the plurality of frames being correspondingly provided with a group of laser chips; any of the plurality of groups of laser chips including a plurality of laser chips, wherein the plurality of groups of laser chips satisfy at least one of following:
different groups of laser chips in the plurality of groups of laser chips are configured to emit laser beams of different colors; or the plurality of laser chips of at least one of the plurality of groups of laser chips are configured to emit the laser beams of different colors; and
a plurality of collimating lens groups corresponding to the plurality of groups of laser chips, respectively, any of the plurality of collimating lens groups being located on a side of a corresponding group of laser chips away from the base, the any collimating lens group including a plurality of collimating lenses, the plurality of collimating lenses corresponding to the plurality of laser chips, respectively, and any of the plurality of collimating lenses being located on a laser-exit path of a corresponding laser chip;
wherein the plurality of laser chips in the any group of laser chips are arranged in a row, and an arrangement direction of the plurality of laser chips is parallel to a slow axis direction of the laser beams emitted by the laser chips, the laser device satisfies at least one of following:
an arrangement direction of the plurality of frames is parallel to a fast axis direction of the laser beams exiting from the any frame; or
an arrangement direction of the plurality of collimating lens groups is parallel to the fast axis direction of the laser beams exiting from the any frame, and an arrangement direction of the plurality of collimating lenses of the any collimating lens group is parallel to the slow axis direction of the laser beams exiting from the corresponding laser chips.

2. The laser device according to claim 1, wherein a length of the any frame in the slow axis direction of the laser beams exiting from the any frame is greater than a length of the any frame in the fast axis direction of the laser beams exiting from the any frame.

3. The laser device according to claim 1, further comprising:
a plurality of conductive regions disposed on the base and located on a same side of the plurality of frames, the plurality of conductive regions being configured to transmit currents to the plurality of groups of laser chips.

4. The laser device according to claim 3, wherein the plurality of conductive regions include:
a plurality of first conductive regions, the laser chips emitting the laser beams of a same color in the plurality of groups of laser chips being connected in series and connected to a same first conductive region, and the laser chips emitting the laser beams of different colors in the plurality of groups of laser chips being connected to different first conductive regions; and
at least one second conductive region, the laser chips emitting the laser beams of different colors in the plurality of groups of laser chips being connected to the at least one second conductive region, and at least two types of laser chips emitting the laser beams of different colors in the plurality of groups of laser chips being connected to a same second conductive region.

5. The laser device according to claim 4, further comprising:
a plurality of power supply terminals disposed on the plurality of frames and penetrating a corresponding frame to be connected to corresponding laser chips, a first portion of the plurality of power supply terminals being connected to the plurality of first conductive regions, respectively, and a second portion of the plurality of power supply terminals being connected to the at least one second conductive region;
wherein the laser chips emitting the laser beams of different colors in the plurality of groups of laser chips are connected to different power supply terminals in the first portion of power supply terminals, the laser chips emitting the laser beams of different colors in the plurality of groups of laser chips are connected to the second portion of power supply terminals, and the at least two types of laser chips emitting the laser beams of different colors are connected to a same power supply terminal in the second portion of power supply terminals.

6. The laser device according to claim 5, wherein the plurality of power supply terminals are connected with the plurality of conductive regions through the base.

7. The laser device according to claim 4, wherein a number of the plurality of first conductive regions is greater than a number of at least one second conductive regions.

8. The laser device according to claim 1, wherein the plurality of groups of laser chips include:
a first group of laser chips including a first type of laser chips; and
a second group of laser chips including a second type of laser chips and a third type of laser chips, a wavelength of the laser beams emitted by the first type of laser chips being greater than a wavelength of the laser beams emitted by the second type of laser chips, and the wavelength of the laser beams emitted by the second type of laser chips being greater than a wavelength of the laser beams emitted by the third type of laser chips;
wherein a number of the first type of laser chips is greater than a number of the second type of laser chips and a number of the third type of laser chips.

9. The laser device according to claim 8, wherein the number of the first type of laser chips is less than or equal to a sum of the number of the second type of laser chips and the number of the third type of laser chips.

10. The laser device according to claim 9, wherein the number of the first type of laser chips is less than the sum of the number of the second type of laser chips and the number of the third type of laser chips, and the number of the second type of laser chips is greater than the number of the third type of laser chips.

11. The laser device according to claim 9, wherein a difference between the wavelengths of the laser beams emitted by any two laser chips in the first type of laser chips is within a range of 4 nm to 10 nm, inclusive.

12. The laser device according to claim 1, wherein the plurality of groups of laser chips include:
a first group of laser chips including a first type of laser chips;
a second group of laser chips including a second type of laser chips; and
a third group of laser chips including a third type of laser chips, a wavelength of the laser beams emitted by the first type of laser chips being greater than a wavelength of the laser beams emitted by the second type of laser chips, and the wavelength of the laser beams emitted by the second type of laser chips being greater than a wavelength of the laser beams emitted by the third type of laser chips;
wherein a number of the first type of laser chips is greater than a number of the second type of laser chips and a number of the third type of laser chips.

13. The laser device according to claim 1, wherein the plurality of laser chips of the any group of laser chips are configured to emit the laser beams of a same color.

14. The laser device according to claim 1, wherein the plurality of groups of laser chips satisfy one of following:
the plurality of laser chips emitting the laser beams of a same color in the any group of laser chips are arranged adjacent to each other; and
at least one laser chip of the at least one group of laser chips is arranged adjacent to at least one laser chip emitting the laser beam of a different color.

15. The laser device according to claim 1, further comprising:
a plurality of heat sinks disposed on the base, at least one of the plurality of laser chips being located on a side of the heat sink away from the base; and
a plurality of prisms disposed on a laser-exit side of at least one corresponding laser chip, the plurality of prisms being configured to propagate the laser beam emitted by the at least one corresponding laser chip in a direction away from the base.

16. The laser device according to claim 1, further comprising:
a plurality of light-transmitting layers corresponding to the plurality of frames, respectively, any of the plurality of light-transmitting layers being located on a side of a corresponding frame away from the base, and the plurality of light-transmitting layers being configured to seal the sides of the plurality of frames away from the base.

17. A laser source assembly, comprising:
a laser device configured to emit laser beams, the laser device including:
a base;
a plurality of frames disposed on the base;
a plurality of groups of laser chips disposed on the base, any of the plurality of frames being correspondingly provided with a group of laser chips, any of the plurality of groups of laser chips including a plurality of laser chips, wherein the plurality of groups of laser chips satisfy at least one of following:
different groups of laser chips in the plurality of groups of laser chips are configured to emit the laser beams of different colors; or the plurality of laser chips of at least one of the plurality of groups of laser chips are configured to emit the laser beams of different colors; and
a plurality of collimating lens groups corresponding to the plurality of groups of laser chips, respectively, any of the plurality of collimating lens groups being located on a side of a corresponding group of laser chips away from the base, the any collimating lens group including a plurality of collimating lenses, the plurality of collimating lenses corresponding to the plurality of laser chips, respectively, and any of the plurality of collimating lenses being located on a laser-exit path of a corresponding laser chip; wherein the plurality of laser chips in the any group of laser chips are arranged in a row, and an arrangement direction of the plurality of laser chips is parallel to a slow axis direction of the laser beams emitted by the laser chips, and the laser device satisfies at least one of following:
an arrangement direction of the plurality of frames is parallel to a fast axis direction of the laser beams exiting from the any frame; or
an arrangement direction of the plurality of collimating lens groups is parallel to the fast axis direction of the laser beams exiting from the any frame, and an arrangement direction of the plurality of collimating lenses of the any collimating lens group is parallel to the slow axis direction of the laser beams exiting from the corresponding laser chips;
a combining lens group located on a laser-exit side of the laser device and configured to combine the laser beams emitted by the laser device;
a light homogenizing component located on a laser-exit side of the combining lens group and configured to increase a divergence angle of the combined laser beam in at least one of a fast axis direction or a slow axis direction, so as to homogenize the combined laser beam; and
a diffusion component located between the combining lens group and the light homogenizing component and configured to receive the combined laser beam and diffuse the combined laser beam; the diffusion component being capable of vibrating or rotating.

18. The laser source assembly according to claim 17, wherein the combining lens group includes:
a first reflecting lens disposed obliquely with respect to a laser-exit direction of the laser device, the first reflecting lens being configured to reflect the laser beam of at least one color in the laser beams of a plurality of colors; and
a first dichroic mirror disposed obliquely with respect to the laser-exit direction of the laser device and located on a laser-exit side of the first reflecting lens, the first dichroic mirror being configured to transmit the laser beam of the at least one color and reflect the laser beam of a remaining color in the laser beams of the plurality of colors.

19. The laser source assembly according to claim 17, wherein the combining lens group includes:
a combining prism, including:
a first surface configured to reflect a laser beam of a first color, transmit a laser beam of a third color, and refract the laser beam of the third color; and
a second surface configured to reflect the laser beam of the third color to the first surface, so that the reflected laser beam of the third color is refracted again by the first surface; and
a combining lens sub-group located on a laser-exit side of the combining prism and configured to combine the laser beams exiting from the combining prism with the laser beam of a remaining color in the laser beams of the plurality of colors;
wherein the combining lens sub-group includes a second dichroic mirror, and the second dichroic mirror satisfies one of following:
the second dichroic mirror is configured to transmit the laser beams of the first color and the third color, and reflect a laser beam of a second color; and
the second dichroic mirror is configured to reflect the laser beams of the first color and the third color, and transmit the laser beam of the second color.

20. The laser source assembly according to claim 19, wherein the combining lens sub-group further includes:
a second reflecting lens located on the laser-exit side of the combining prism and configured to reflect the laser beams of the first color and the third color; and
a third reflecting lens configured to reflect the laser beam of the second color;
wherein the second dichroic mirror is located on laser-exit sides of the second reflecting lens and the third reflecting lens and configured to transmit the laser beams of the first color and the third color and reflect the laser beam of the second color.
